(19) United States
(12) Patent Application Publication
(10) Pub. No.: US 2023/0392022 A1
(43) Pub. Date: Dec. 7, 2023

(54) MULTIFUNCTIONAL HYBRID NANOFILLERS AS SENSITIZERS/CO-INITIATORS FOR PHOTOPOLYMERIZATION

(71) Applicant: Nanyang Technological University, Singapore (SG)

(72) Inventors: Xiao HU, Singapore (SG); Alamelu Suriya SUBRAMANIAN, Singapore (SG); Hui CHEN, Singapore (SG); Yong LU, Singapore (SG)

(21) Appl. No.: 18/033,951

(22) PCT Filed: Oct. 28, 2021
(86) PCT No.: PCT/SG2021/050659

§ 371 Date: Apr. 26, 2023

(30) Foreign Application Priority Data
Oct. 28, 2020 (SG) 10202010710R

(51) Int. Cl. C09D 4/06; C09D 5/24; C09D 7/62; C09D 7/63; C09D 163/00; C09D 133/04; C09D 7/80; B33Y 70/10

(52) U.S. Cl. CPC C09D 4/06; C09D 5/24; C09D 7/62; C09D 7/63; C09D 163/00; C09D 133/04; C09D 7/80; B33Y 70/10; B29C 64/106

(57) ABSTRACT

Disclosed herein is a formulation that includes a hybrid composite material, at least one photopolymerizable monomer, one or both of a free radical photoinitiator and an oxidizable radical co-producer. The hybrid composite material is formed from an organic semiconducting material and a conductive material, where the organic semiconducting material is bonded to the conductive material. In specific embodiments, the hybrid composite material is polydopamine/multiwalled carbon nanotubes (PDA/MWCNTs) hybrid composite or polydopamine/gallium zinc oxide (PDA/GZO) hybrid composite. Also disclosed herein are a method of initiating and/or sensitizing photopolymerization and method of additive manufacture via photopolymerization using said formulation.

### FIELD OF INVENTION

This invention relates to a method of initiating and/or sensitizing photopolymerization. The method of initiating and/or sensitizing photopolymerization may be applied in additive manufacturing, e.g., to facilitate/enhance curing of 3D-printed polymer and polymer (nano)composites. Other uses for the method may also include as a coating and/or as an adhesive, amongst others. As such, the method also applies to a material that may be used to effect said methods.

### BACKGROUND

The listing or discussion of a prior-published document in this specification should not necessarily be taken as an acknowledgement that the document is part of the state of the art or is common general knowledge.

Photopolymerization has received renewed interest due to emerging technologies such as 3D printing or additive manufacturing (AM) of polymeric materials. AM processes such as stereolithography (SLA) and polyjetting function by the principle of building structures through layer by layer polymerization of light curable thermosetting materials. SLA and Digital Light Projection (DLP) technologies have found applications in medical and dental devices, complex lightweight aerospace parts, and structural prototypes in engineering and architectural industries. However, their applications are vastly limited to use as conceptual prototypes rather than as functional elements due to low mechanical strength that restricts their wide industrial applications (Wang, X. et al., Compos. B. Eng. 2017, 110, 442-458). Therefore, reinforcement nanofillers have been added to photoactive formulations. Nevertheless, the strong light absorbing nature of reinforcement fillers like MWCNT, GO and graphene will dampen the polymerization rate due to light absorption and blocking (Eng, H. et al., Rapid Prototyp. J. 2017, 23, 129-136).

Further, SLA and polyjetting in practice are still vastly limited to the acrylate/methacrylate families of monomers due to the very fast polymerization rates required in these high speed in-line processes. Acrylate monomers are suitable due to their rapid free radical polymerization mechanism and the availability of suitable free radical initiators with absorption ranges in the vicinity of 385-400 nm where typical SLA 3D printer machine's light sources operate in. However, these materials still require an off-line post cure step. Tack-free cure within seconds of exposure in the near UV (e.g. 365 nm, 385 nm) or visible light (405 nm) region where most SLA type machines operate would be ideal for SLA. 3D printing of epoxy is an alternative to acrylates. Epoxy monomers offer several advantages over acrylates, such as lower shrinkage, better mechanical strength, no oxygen toxicity, and controlled polymerization. Notably, the major factor that impedes the development of further resins is the slow rate of polymerization.

Recently, there has been a lot of interest in free radical promoted cationic polymerization (FRPCP), whereby free radicals generated by free radical photoinitiators absorbing at higher wavelengths induce the cationic polymerization process. However, the conversion rates/times reported in these systems were still not fast enough for high-speed processes like AM.

Hence, there is a need to develop new photoinitiating systems to enhance polymerization at longer wavelengths, lower energies, and faster rate, and to discover new photopolymer resins of acrylate and epoxy with better mechanical properties, thermal and electrical conductivity, and fire retardancy through reinforcement with nanofillers for application in AM.

### SUMMARY OF INVENTION

Aspects and embodiments of the invention will now be discussed by reference to the following numbered clauses.
1. A formulation comprising:
   a hybrid composite material;
   at least one photopolymerizable monomer;
   one or both of a free radical photoinitiator and an oxidizable radical co-producer, wherein
   the hybrid composite material comprises:
   an organic semiconducting material; and
   a conductive material, wherein
      the organic semiconducting material is bonded to the conductive material.
2. The formulation according to Clause 1, wherein the organic semiconducting material is selected from one or more of the group consisting of a bioconjugated biomolecule semiconductor and a conjugated organic material with semiconducting properties.
3. The formulation according to Clause 2, wherein:
(Ai) the bioconjugated biomolecule semiconductor is selected from one or more of the group consisting of a polydopamine, a polyepinephrine, a polymelanine, a polyeumelanin, optionally wherein the organic semiconducting material is a polydopamine; and
(Bi) the conjugated organic material with semiconducting properties is a monomer or, more particularly an oligomer or a polymer formed from monomers with extended π-conjugated systems, optionally wherein formed from one or more of the group consisting of a thiophene, a phthalocyanine, a pyrydine, an anthracene, a pentacene, a benzoxazine and their co-ordination complexes with a transition metal (e.g. where the transition meal is selected from one or more of the group consisting of Zn, Fe, Mn, Cu, Pt, Ni, and Au).
4. The formulation according to any one of the preceding clauses, wherein the conductive material is selected from one or more of the group consisting of a conductive carbon material and a plasmonic, transparent conductive metal oxide, and metal particles.
5. The formulation according to Clause 4, wherein the conductive material is selected from one or more of the group consisting of a carbon fibre, a carbon whisk or, more particularly, a multiwalled carbon nanotube (MWCNT), graphene oxide (GO), reduced graphene oxide (rGO), a carbon black, carbon spheres, gallium zinc oxide (GZO), antimony tin oxide (ATO), aluminum zinc oxide (AZO), gallium indium-tin oxide (GaITO), Ag and Au, optionally wherein the conductive material is a multiwalled carbon nanotube and/or GZO.
6. The formulation according to any one of the preceding clauses, wherein the ratio of the organic semiconducting material to conductive material is from 0.1:99.9 to 25:75 by weight, such as from 5:95 to 25:75 by weight, such as from 15:95 to 25:75 by weight, such as 20:80 by weight.
7. The formulation according to any one of the preceding clauses, wherein the formulation further comprises at least one cationic photoinitiator.
8. The formulation according to any one of the preceding clauses, wherein the hybrid composite material has at least one dimension that is less than 500 nm.
9. The formulation according to any one of the preceding clauses, wherein the conductive material comprises a first conductive material and a second conductive material, and wherein the organic semiconducting material is bonded to the first conductive material and the second conductive material or vice versa.
10. The formulation according to Clause 9, wherein the first and second conductive materials are selected from a conductive material as described in Clause 4 or Clause 5, provided that the first and second conductive materials are not the same.
11. The formulation according to any one of the preceding clauses, wherein the organic semiconducting material comprises a first organic semiconducting material and a second organic semiconducting material, and wherein the conductive material is bonded to the first organic semiconducting material and the second organic semiconducting material or vice versa, optionally wherein the first and second organic semiconducting materials are selected from an organic semiconducting material as described in Clause 2 or Clause 3, provided that the first and second organic semiconducting materials are not the same.
12. The formulation according to any one of Clauses 1 to 8, wherein the hybrid composite material is selected from the list:
(i) polydopamine bonded to multiwalled carbon nanotubes; and
(ii) polydopamine bonded to GZO.
13. A kit of parts comprising:
(A) a first formulation comprising a hybrid composite material as described in any one of Clauses 1 to 12 and a first portion of at least one photopolymerizable monomer; and
(B) a second formulation comprising a second portion of the at least one photopolymerizable monomer and one or both of a free radical photoinitiator and an oxidizable radical co-producer.
14. The formulation according to any one of Clauses 1 to 12, or the kit of parts according to Clause 13, wherein the formulation of any one of Clauses 1 to 12 or first formulation and/or second formulation of Clause 13 further comprises one or more of the following components:
(ai) a co-initiator;
(aii) a co-sensitizer;
(aiii) a photostabilizer;
(aiv) an inhibitor
(av) a rheology modifier;
(avi) a tackifier; and
(avii) in a kit of parts according to Clause 13, a cationic photoinitiator, optionally wherein the cationic photoinitiator is present as part of the first formulation of said kit of parts.
15. The formulation according to any one of Clauses 1 to 12 and Clause 14, or the kit of parts according to Clause 13 or Clause 14, wherein the at least one photopolymerizable monomer is a monomer having a functional group selected from one or more of the group consisting of thiolene, epoxide, acrylate, and cyclic oxide ring, optionally wherein the at least one photopolymerizable monomer is a monomer having a functional group selected from one or more of the group consisting of epoxide, acrylate, and cyclic oxide ring.
16. The formulation according to any one of Clauses 1 to 12 and 14 to 15, or the kit of parts according to any one of Clauses 13 to 15, wherein the at least one photopolymerizable monomer is a monomer having from 1 to 4 functional groups per monomeric unit, such as 2 functional groups.
17. The formulation according to any one of Clauses 1 to 12 and 14 to 16, or the kit of parts according to any one of Clauses 13 to 16, wherein the at least one photopolymerizable monomer is a monomer selected from one or more of the following list:
(bi) epoxycyclohexylmethyl-3′,4′-epoxycyclohexane carboxylate;
(bii) bis(oxiran-2-ylmethyl) cyclohexane-1,2-dicarboxylate;
(biii) 2-[[4-[1-methyl-1-[4-(oxiran-2-ylmethoxy)phenyl]ethyl]phenoxy]methyl]oxirane;
(biv) 2-[2,2-bis(oxiran-2-ylmethoxymethyl)butoxymethyl]oxirane;
(bv) methyl methacrylate;
(bvi) 4-prop-2-enoyloxybutyl prop-2-enoate;
(bvii) 2,2-bis(prop-2-enoyloxymethyl)butyl prop-2-enoate;
(bix) 6-[4-[1-methyl-1-[4-(4-oxohex-5-enoxy)phenyl]ethyl]phenoxy]hex-1-en-3-one;
(bx) hexane-1,6-dithiol;
(bxi) [4-(sulfanylmethyl)phenyl]methanethiol; and
(bxii) 6,6-bis(3-oxo-5-sulfanyl-pentyl)-1,11-bis(sulfanyl)undecane-3,9-dione.
18. The formulation or kit of parts according to Clause 17, wherein the at least one photopolymerizable monomer is a monomer selected from one or more of the following list:
(ci) epoxycyclohexylmethyl-3′,4′-epoxycyclohexane carboxylate;
(cii) bis(oxiran-2-ylmethyl) cyclohexane-1,2-dicarboxylate;
(ciii) 2-[[4-[1-methyl-1-[4-(oxiran-2-ylmethoxy)phenyl]ethyl]phenoxy]methyl]oxirane;
(civ) 2-[2,2-bis(oxiran-2-ylmethoxymethyl)butoxymethyl]oxirane;
(cv) methyl methacrylate;
(cvi) 4-prop-2-enoyloxybutyl prop-2-enoate;
(cvii) 2,2-bis(prop-2-enoyloxymethyl)butyl prop-2-enoate; and
(cviii) 6-[4-[1-methyl-1-[4-(4-oxohex-5-enoxy)phenyl]ethyl]phenoxy]hex-1-en-3-one,
optionally wherein the at least one photopolymerizable monomer is one or both of epoxycyclohexylmethyl-3′,4′-epoxycyclohexane carboxylate and methyl methacrylate (e.g. the at least one photopolymerizable monomer is epoxycyclohexylmethyl-3′,4′-epoxycyclohexane carboxylate).
19. The formulation according to any one of Clauses 1 to 12 and 14 to 18, or the kit of parts according to any one of Clauses 13 to 18, wherein one or more of the following apply:
(di) the oxidizable radical co-producer, when present, is selected from one or more of the group consisting of a carbazole, an amine, and a silane, optionally wherein the oxidizable radical co-producer is N-vinylcarbazole (NVK);
(dii) the free radical photoinitiator, when present, is selected from one or more of the group consisting of a Type I and a Type II free radical photoinitiator, optionally wherein the free radical photoinitiator is selected from one or more of the group consisting of a hydroxy alkylphenone, dialkoxyacetophenone, a benzoin ether, a benzyl ketal and, more particularly, bis-acyl phosphine oxide, diphenyl (2,4,6-trimethylbenzoyl)phosphine oxide, an amino alkyl phenone, a benzophenone, and a thioxanthone; and
(diii) when the formulation or the kit of parts comprises a cationic photoinitiator, the cationic photoinitiator is an iodonium salt and/or a sulfonium salt, optionally wherein the iodonium salt is selected from one or more of the group consisting of diphenyliodonium hexafluorophosphate, bis(4-tert-butylphenyl)iodonium hexafluorophosphate, and iodonium hexafluoroantimonate.
20. The formulation according to any one of Clauses 1 to 12 and 14 to 19,
wherein one or both of the following apply:
(ei) the amount of the free radical photoinitiator is from 0.1 to 5 wt % of the total weight of the formulation; and
(eii) the amount of the oxidizable radical co-producer is from 0.1 to 5 wt % of the total weight of the formulation, or
   the kit of parts according to any one of Clauses 13 to 19, wherein one or both of the following apply:
(fi) the amount of the free radical photoinitiator is from 0.1 to 5 wt % of the total weight obtained by the combination of the first and second formulations; and
(fii) the total amount of the oxidizable radical co-producer in the second formulation is from 0.2 to 10 wt %, such that it provides from 0.1 to 5 wt % of the total weight obtained by the combination of the first and second formulations.
21. The formulation according to any one of Clauses 7 and 8 to 12 and 14 to 20 as dependent upon Clause 7, wherein the amount of the cationic photoinitiator is from 0.1 to 5 wt % of the total weight of the formulation, or the kit of parts according to any one of Clauses 14 to 20, wherein when a cationic photoinitiator is present, it forms from 0.1 to 5 wt % of the total weight of the combination of the first and second formulations.
22. A method of initiating and/or sensitizing photopolymerisation, comprising:
(gi) mixing a hybrid composite material as described in any one of Clauses 1 to 12 with a composition comprising:
   at least one photopolymerizable monomer; and
   one or both of a free radical photoinitiator and an oxidizable radical co-producer to form a mixture; and
(gii) exposing the mixture to a light in order to provide a polymer product.
23. The method according to Clause 22, wherein the mixture further comprises a cationic photoinitiator.
24. The method according to Clause 22 or Clause 23, wherein the mixture is a formulation as described in any one of Clauses 1 to 12 and 14 to 21, or is a mixture formed from the combination of a first formulation and a second formulation of a kit of parts as described in any one of Clauses 13 to 21.
25. The method according to any one of Clauses 22 to Clause 24, wherein the wavelength of the light is from 250 to 1,200 nm, such as from 320 to 420 nm.
26. A method of additive manufacture, the method comprising the steps of:
(hi) providing a mixture comprising:
   a hybrid composite material as described in any one of Clauses 1 to 12;
   at least one photopolymerizable monomer; and
   one or both of a free radical photoinitiator and an oxidizible radical co-producer;
(hii) forming a layer using the mixture according to a design;
(hiii) subjecting the layer to light to provide a polymer; and
(hiv) repeating steps (hii) and (hiii) until the desired design is complete.
27. The method according to Clause 26, wherein the mixture further comprises a cationic photoinitiator.
28. The method according to Clause 26 or Clause 27, wherein the mixture is a formulation as described in any one of Clauses 1 to 12 and 14 to 21, or is a mixture formed from the combination of a first formulation and a second formulation of a kit of parts as described in any one of Clauses 13 to 21.
29. The method according to any one of Clauses 26 to 28, wherein the wavelength of the light is from 250 to 1,200 nm, such as from 320 to 420 nm.

### DRAWINGS

FIG. 1 depicts the secondary electron images (SEI) of (a) neat PDA nanoparticles synthesized in DI water; (b) neat PDA nanoparticles synthesized in water/ethanol mixture. Scale bars 1 μm; and (c) differential photocalorimetry (DPC) of 3,4-epoxycyclo hexylmethyl-3′,4′-epoxycyclohexane carboxylate (ECC) resin with PDA photosensitizer/co-initiator upon UV-Vis irradiation with Iod/NVK (2 wt %/3 wt %).

FIG. 2 depicts the dispersion of PDA/MWCNT and pristine MWCNT at 0 min and 24 h.

FIG. 3 depicts the dispersion of MWCNT-COOH (left), PDA/MWCNT (middle), MWCNT-NH₂ (right) at (a) 0 min; (b) 10 min; and (c) 30 days.

FIG. 4 depicts the process methodology: PDA and MWCNT nanohybrids as photosensitizer/co-initiator.

FIG. 5 depicts the DPC of ECC resin with (a) PDA20/MWCNT80, PDA without or with pristine MWCNT nanofillers (constant 0.5 wt % of MWCNT component) with Iod/NVK (2 wt %/3 wt %) resin and ECC/Iod (98 wt %/2 wt %) cationic system upon UV-Vis irradiation; and (b) PDA20/MWCNT80 (where 0.125 wt % is PDA component and 0.5 wt % is MWCNT component) and commercial photoinitiator Irgacure 819 (BAPO), without or with pristine MWCNT upon UV-Vis irradiation with Iod/NVK; 2 wt %/3 wt % resin. With the same amount of PDA component (0.125 wt %) in (a), the PDA20/MWCNT80 nanohybrid system shows much higher conversion and reaction rate; TEM images of (c) pristine MWCNT and (d) nanohybrid PDA20/MWCNT80, all scale bars are 50 nm; and (e) comparison of degree of conversion (DOC) for various sensitizers/co-initiators with Iod/NVK (2 wt %/3 wt %) resin and ECC/Iod (98 wt %/2 wt %) cationic system.

FIG. 6 depicts the DPC of ECC resin with (a) PDA, photosensitizer/co-initiator upon ultraviolet-visible (UV-Vis) irradiation with Iod/NVK (2 wt %/3 wt %). The inset (same axes) shows extended irradiation time with no further activity; (b) for (Iod/NVK; 2 wt %/3 wt %) systems, with no other photo(co)initiator/sensitizer, the addition of pristine MWCNT reduces reactivity; and (c) synergistic effect of PDA/MWCNT-COOH nanohybrid with Iod/NVK (2 wt %/3 wt %) only observed when MWCNT component is s 0.5 wt %.

FIG. 7 shows that the addition of MWCNT slows reaction due to light blocking and absorption with 0.25 wt % PDA series.

FIG. 8 depicts (a) fourier transform infrared spectroscopy (FTIR) curves for polymerization of epoxy resin with PDA20/MWCNT80 nanohybrid photosensitizer/co-initiator upon UVA (315-400 nm) irradiation with Iod/NVK (2 wt %/3 wt %). The inset zooms to show the change in the intensity of the characteristic band at 1080 cm¹, indicating formation of C—O—C bonds upon breaking up of the glycidyl groups on ECC monomer; (b) DOC from FTIR analysis, of ECC resin with PDA/MWCNT-COOH, PDA photosensitizer/co-initiator with or without pristine MWCNT as nanofiller, upon UVA irradiation with Iod/NVK (2 wt %/3 wt %); and (c) DOC from FTIR analysis, of aged ECC resins with 0.625 wt % PDA20/MWCNT80 nanohybrids in Iod/NVK (2 wt %/3 wt %).

FIG. 9 depicts the (a) UV-Vis absorbance of dopamine (DA) monomer, PDA, PDA/MWCNT nanohybrid and NVK; and (b) emission spectra of PDA and PDA/MWCNT nanohybrid exhibiting fluorescence quenching upon excitation at 290 and 365 nm. For both the excitation wavelengths given, the fluorescence peak was found to be quenched in the PDA/MWCNT nanohybrids via photoinduced electron transfer, indicating suppression of charge recombination effect which is responsible for the performance enhancement observed with the substantial increase in DOC, conversion rate and shortened time to peak exotherm.

FIG. 10 depicts the UV-Vis absorbance of phenylbis (2,4,6-trimethyl benzoyl) phosphine oxide (BAPO).

FIG. 11 depicts (a) contact angle of uncured ECC resin with different photoinitiators/nanofillers on PTFE and glass substrates, all values have deviation of ±0.5°, PDA surface modification on MWCNT allows better wetting of the ECC resin; (b) UV-Vis transmission curves; and (c) photograph of UV-Vis cured ECC films with 0.5 wt % various photoinitiators/nanofillers.

FIG. 12 depicts (a) reactive components of acrylate resin; (B) cure depth curves of acrylate resin with pristine and modified MWCNT, with PDA/MWCNT showing higher curing depth and slope (depth of penetration) against energy dosage; (C) cure depth at given exposure times, the light intensity was set to 8.8 mW/cm²; and (D) cured tabs used for measuring depth at given exposure times.

FIG. 13 depicts (a) reactive components of acrylate resin; (b) cure depth curves of acrylate resin with pristine and modified MWCNT, with PDA/MWCNT showing higher curing depth and slope (depth of penetration) against energy dosage; (c) cure depth at given exposure times, the light intensity was set to 8.8 mW/cm²; and (d) DLP printed honeycomb samples of (i) unfilled acrylate resin; (ii) pristine MWCNT filled acrylate (printed with extended exposure time); and (iii-v) PDA/MWWCNT filled acrylate resin. Honeycomb sample dimension is ˜10×9×8 mm (CAD drawing).

FIG. 14 depicts a working curve for polymer resin for 3D printing: cure depth and depth of penetration evaluation for acrylate resin with BAPO photoinitiator and PDA/MWCNT photosensitizer/co-initiator for nanocomposite resin photopolymerization for DLP printing.

FIG. 15 depicts (a) reaction route for ECC polymerization with PDA nanoparticles or PDA/MWCNT nanohybrid sensitizers/co-initiators; and (b) proposed mechanism for photo sensitization/co-initiation by PDA/MWCNT nanohybrid.

FIG. 16 depicts (a) absorbance intensity of methylene blue (MB) with exposure time in the presence of PDA nanoparticles (PDA NP) and PDA/MWCNT nanohybrid structures. The evolution of reactive species leads to reaction with dye molecules and yield of degradation products; and (b) Degradation of methylene blue in the presence of PDA/MWCNT, PDA NP and pristine MWCNT with exposure time of 0 and 20 min.

FIG. 17 depicts the stress strain curves for post cured samples.

FIG. 18 depicts the DPC curves for acrylate resin with 0.5 wt % pristine MWCNT and 0.5 wt % PDA/MWCNT.

FIG. 19 depicts neat acrylate resin, 0.5 wt % pristine MWCNT in acrylate resin, and 0.5 wt % PDA/MWCNT in acrylate resin.

FIG. 20 depicts TEM of (a) PDA22/GZO78; (b) TGA of GZO and PDA modified GZO in air; (c) DPC of ECC resin with PDA/GZO photosensitizer/co-initiator upon UV-Vis irradiation with Iod/NVK (2 wt %/3 wt %); and (d) DOC from FTIR of ECC resin with PDA/GZO photosensitizer/co-initiator upon UVA (315-400 nm) irradiation with Iod/NVK (2 wt %/3 wt %). Dotted lines are the fitted logarithmic graphs from respective data set.

FIG. 21 depicts TEM of neat (a) GZO; (b) ATO; and DPC of ECC resin with (c) GZO transparent conductive oxide; and (d) ATO transparent conductive oxide photosensitizer/co-initiator upon UV-Vis irradiation with Iod/NVK (2 wt %/3 wt %) and ECC/Iod (98 wt %/2 wt %) cationic system.

FIG. 22 depicts (a) UV-Vis absorbance of PDA, GZO, PDA22/GZO78 and NVK; and (b) emission spectra of GZO and PDA/GZO.

FIG. 23 depicts (a) proposed mechanism for photo sensitization/co-initiation by neat GZO; (b) reaction route for ECC polymerization with radicals formed; and (c) proposed mechanism for photo sensitization/co-initiation by PDA/GZO.

FIG. 24 depicts (a) output spectrum of solar simulator lamp (Hg—Xe lamp); and (b) absorption spectrum of GZO nanoparticles in UV-Vis-NIR regions.

FIG. 25 depicts (a) photograph of UV-Vis cured transparent ECC films with various photoinitiators/nanofillers; and (b) UV-Vis transmission curves of ECC films with GZO based photoinitiators/nanofillers.

FIG. 26 depicts various arrangements where the semiconducting material bonded to/modified with two or more conductive materials.

### DESCRIPTION

In a first aspect of the invention, there is disclosed a formulation comprising:
a hybrid composite material;
at least one photopolymerizable monomer;
one or both of a free radical photoinitiator and an oxidizable radical co-producer, wherein
the hybrid composite material comprises:
an organic semiconducting material; and
a conductive material, wherein
   the organic semiconducting material is bonded to the conductive material.

The hybrid composite material above may be useful in the light curing of monomeric materials, particularly during an additive manufacturing process. Additionally, and as discussed further in the examples section hereinbelow, the hybrid composite material has also been used in the photodegradation of a dye, which demonstrates radical evolution and indicates that the material may have further utility in other photoactive applications such as photocatalysis and the like.

In embodiments herein, the word “comprising” may be interpreted as requiring the features mentioned, but not limiting the presence of other features. Alternatively, the word “comprising” may also relate to the situation where only the components/features listed are intended to be present (e.g. the word “comprising” may be replaced by the phrases “consists of” or “consists essentially of”). It is explicitly contemplated that both the broader and narrower interpretations can be applied to all aspects and embodiments of the present invention. In other words, the word “comprising” and synonyms thereof may be replaced by the phrase “consisting of” or the phrase “consists essentially of” or synonyms thereof and vice versa.

The phrase, “consists essentially of” and its pseudonyms may be interpreted herein to refer to a material where minor impurities may be present. For example, the material may be greater than or equal to 90% pure, such as greater than 95% pure, such as greater than 97% pure, such as greater than 99% pure, such as greater than 99.9% pure, such as greater than 99.99% pure, such as greater than 99.999% pure, such as 100% pure.

As noted hereinbefore, the hybrid composite material, may be formed from an organic semiconducting material and a conductive material, where the organic semiconducting material is bonded to the conductive material. Any suitable type of bonding may be used and will depend on the surface groups on the conductive material(s). For example, the bonding may be via one or more of covalent bonding, pi-pi stacking, hydrogen bonding (e.g., via a pendant OH group), Van der Waals forces, chelation (e.g., metal ion chelation), complex formation (e.g., catechol metal complexation (especially with Fe³⁺)) and the like. Particular sub-types of bonding that may be mentioned include, but are not limited to crosslinking, cohesion coupling, and addition reactions (e.g., in quinone/semi-quinone form) etc.

The hybrid composite material may have at least one dimension that is less than 500 nm.

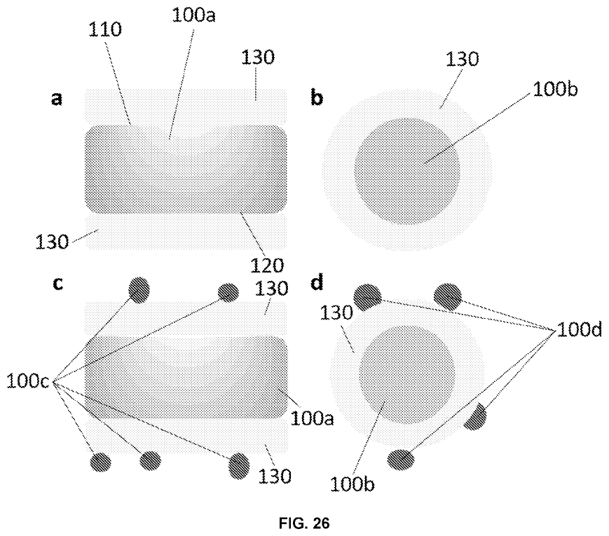

The hybrid composite material may also comprise a semiconducting material bonded to/modified with two or more conductive materials (or vice-versa). The hybrid composite may also comprise a mixture of different groups of bonded semiconducting material-conductive materials. The amount of hybrid composite in the mixture may be from more than 0 wt % and up to 5 wt %. Any suitable arrangement when there is more than one of the organic semiconducting material and the conductive material may be envisaged. Examples of suitable arrangements are provided in FIG. 26. When there is one conductive component FIG. 26a may be used to show two differing arrangements. In the first arrangement, FIG. 26a shows a situation where a conductive component 100a has a top and bottom surface 110 and 120 that are both covered with the organic semiconducting material 130 (as will be appreciated only one surface (or part thereof) needs to be so covered). In an alternative arrangement, FIG. 26a shows a cross section of the hybrid composite material, where a conductive component 100a has a 3-D shape that has a single continuous surface (110/120) (e.g. the conductive component 100a has a cylindrical, ellipsoid, rod-like, or wire-like shape), which is covered with the organic semiconducting material 130 (as will be appreciated only one surface (or part thereof) needs to be so covered). In other arrangements (see FIG. 26b), the conductive component 100b may be spherical with the organic semiconducting material 130 covering this spherical conductive component 100b. FIG. 26c corresponds to the arrangements described above for FIG. 26a, except that it includes a second conductive component 100c, which may be in contact with a surface of the organic semiconducting material 130 not directly in contact with the first conductive material 100a. Similarly, FIG. 26d corresponds to FIG. 26b, except that it includes a second conductive component 100d, which is in contact with a surface of the organic semiconducting material 130 not directly in contact with the first conductive material 100b.

Thus, the organic semiconducting material may be bonded to a first conductive material and a second conductive material or vice versa.

The organic semiconducting material may be selected from any suitable material. For example, the organic semiconducting material is selected from one or more of the group consisting of a bioconjugated biomolecule semiconductor and a conjugated organic material with semiconducting properties. Any suitable bioconjugated biomolecule semiconductor may be used, for example, the bioconjugated biomolecule semiconductor may be selected from one or more of the group consisting of a polydopamine, a polyepinephrine, a polymelanine, a polyeumelanin. Any suitable conjugated organic material with semiconducting properties may be used, for example, the conjugated organic material with semiconducting properties may be selected from one or more of the group consisting of a monomer or, more particularly an oligomer or a polymer formed from monomers with extended 7t-conjugated systems, optionally wherein formed from one or more of the group consisting of a thiophene, a phthalocyanine, a pyrydine, an anthracene, a pentacene, a benzoxazine and their co-ordination complexes with a transition metal (e.g. where the transition meal is selected from one or more of the group consisting of Zn, Fe, Mn, Cu, Pt, Ni, and Au). As will be appreciated, when there are two or more (e.g. a first and a second) organic semiconducting materials, said organic semiconducting materials are not the same material, but different materials (e.g. selected from the list mentioned above).

In particular embodiments of the invention that may be mentioned herein the organic semiconducting material may be a polydopamine.

Any suitable conductive material may be used in embodiments of the invention. For example, the conductive material may be selected from a carbon fibre, a carbon whisk or, more particularly, a multiwalled carbon nanotube (MWCNT), graphene oxide (GO), reduced graphene oxide (rGO), a carbon black, carbon spheres, gallium zinc oxide (GZO), antimony tin oxide (ATO), aluminum zinc oxide (AZO), gallium indium-tin oxide (GaITO), Ag, Au, alloys thereof (where possible) and mixtures thereof (e.g. when there are two or more conductive materials present). In particular embodiments of the invention, the conductive material may be a multiwalled carbon nanotube and/or GZO. As will be appreciated, when there are two or more (e.g. a first and a second) conductive material, said conductive materials are not the same material, but different materials (e.g. selected from the list mentioned above).

Without wishing to be bound by theory, it is believed that the conductive material may play a dual role as mechanical reinforcement and as a nanohybrid heterogeneous photosensitizer/co-initiator.

Any suitable ratio of the semiconducting material to conductive material may be used. For example, the ratio of the semiconducting material to conductive material may be from 0.1:99.9 to 25:75 by weight, such as from 5:95 to 25:75 by weight, such as from 15:95 to 25:75 by weight, such as 20:80 by weight. It will be appreciated that these ratios may refer to the total amount of the semiconducting material and the conductive material (e.g. when there is more than one semiconducting material and/or conductive material).

In particular embodiments that may be mentioned herein, the hybrid composite material may be selected from the list:
(i) polydopamine (PDA) bonded to multiwalled carbon nanotubes (MWCNT); and
(ii) polydopamine bonded to GZO. Suitable ratios of the components may be those mentioned hereinbefore.

MWCNT modified by bioconjugated semiconducting PDA was compared with pristine MWCNT and was found to enhance several aspects of a composite photopolymerformulation:
improved dispersion of the hybrid composite material due to enhanced colloidal stability of the modified PDA/MWCNT leading to less agglomeration;
the light blocking effect of the hybrid composite material while 3D printing leading to enhanced printability (acts as photoabsorber). As discussed below, the light blocking of pristine MWCNT is so high that the print quality is very poor. However, when a hybrid composite material is used, as discussed herein, the light blocking is not excessive and is balanced by the generation of radical/active species, leading to an improved print quality and/or resolution;
generation of free radicals/active species upon irradiation of the PDA/MWCNT hybrid composite material also leads to enhanced printability of the composite resin; and
the PDA/MWCNT filled resin exhibits better adhesion and lap shear strength compared to pristine MWCNT filled resin system. It is believed that similar advantages also apply to the other combinations disclosed herein.

In addition, it is noted that there is a substantial improvement in the reactivity of acrylate MWCNT nanocomposite resins and epoxy monomers/nanocomposite resins with the incorporation of nanohybrid sensitizer/co-initiator nanofillers upon irradiation together with providing mechanical reinforcement. Typically, MWCNTs (unmodified or aminated/carboxylated) reduce the photopolymerization rate of monomers as they are strongly light absorbing and light blocking. Thus, the current invention relates to a new class of nanohybrid sensitizers/co-initiators that have a higher reactivity enabling potential applications in UV-Vis curing of nanocomposites through 3D printing technologies such as SLA and DLP.

The use of an organic semiconducting material (e.g. PDA) with a transparent conductive oxide (TCO, e.g. GZO) is also disclosed herein. For example, a PDA/TCO system allows 3D printing of functional composites in resin systems that contain said materials.

As noted hereinbefore, the formulation may include one or both of a free radical photoinitiator and an oxidizable radical co-producer.

Any suitable oxidizable radical co-producer may be used, when it is present in a formulation described herein. Suitable oxidizable radical co-producers include, but are not limited to a carbazole, an amine, a silane, and combinations thereof. In particular embodiments that may be mentioned herein, the oxidizable radical co-producer may be N-vinylcarbazole (NVK).

When present in a formulation, the amount of the oxidizable radical co-producer may be from 0.1 to 5 wt % of the total weight of the formulation.

Any suitable free radical photoinitiator may be used, when it is present in a formulation described herein. For example, the free radical photoinitiator may be a Type I and/or a Type II free radical photoinitiator. Suitable free radical photoinitiators that may be mentioned herein include, but are not limited to bis-acyl phosphine oxide, diphenyl (2,4,6-trimethylbenzoyl)phosphine oxide, an amino alkyl phenone, a benzophenone, a thioxanthone, and combinations thereof.

When present in a formulation, the amount of the free radical photoinitiator in the formulation may be from 0.1 to 5 wt % of the total weight of the formulation.

The formulations disclosed herein may also further comprise a at least one cationic photoinitiator. Suitable classes of cationic photoinitiators that may be mentioned herein are iodonium salts and sulfonium salts, as well as combinations thereof. Suitable iodonium salts that may be mentioned herein include, but are not limited to diphenyliodonium hexafluorophosphate, bis(4-tert-butylphenyl)iodonium hexafluorophosphate, iodonium hexafluoroantimonate, and combinations thereof.

When present in a formulation, the amount of the cationic photoinitiator may be from 0.1 to 5 wt % of the total weight of the formulation.

It will be appreciated that the exact mix of these initiating materials may depend on the desired use of the formulation. For example, the formulations disclosed herein may be suitable for use in free-radical polymerisation (FRP) and/or free radical promoted cationic polymerisation (FRPCP). In systems that make use of FRPCP, then a cationic photoinitiator is present in combination with one or both of a free radical photoinitiator and an oxidizable radical co-producer. In systems that make use of FRP, then the formulation must contain one or both of a free radical photoinitiator and an oxidizable radical co-producer and may also optionally contain a cationic photoinitiator, though this latter component is not essential in such formulations.

The at least one photopolymerizable monomer may be selected from any suitable such material. For example, the at least one photopolymerizable monomer may be selected from a material that may undergo FRP and/or FRPCP. Examples of suitable at least one photopolymerizable monomers include, but are not limited to a monomer having a functional group selected from one or more of the group consisting of thiolene, epoxide, acrylate, and cyclic oxide ring. In particular embodiments that may be mentioned herein, the at least one photopolymerizable monomer may be a monomer having a functional group selected from one or more of the group consisting of epoxide, acrylate, and cyclic oxide ring. Each of the at least one photopolymerizable monomers present in any given formulation may have from 1 to 4 functional groups per monomeric unit. In particular embodiments, the at least one photopolymerizable monomer may have 2 functional groups per monomeric unit.

Monomers having epoxide ring functional groups may comprise from one to four (e.g. 2 or 3) epoxide ring functional groups per monomeric unit. There is no particular limitation on the structure of the monomeric unit, which may comprise one or more structural units selected from linear or branched aliphatic, cycloaliphatic and aromatic. As will be appreciated, the monomers may be substituted by further functional groups (e.g. OH, halo (e.g. F, Br, Cl, I) and the like). Examples of suitable monomers having epoxide ring functional groups may include, but are not limited to:
(aa) epoxycyclohexylmethyl-3′,4′-epoxycyclohexane carboxylate;
(ab) bis(oxiran-2-ylmethyl) cyclohexane-1,2-dicarboxylate;
(ac) 2-[[4-[1-methyl-1-[4-(oxiran-2-ylmethoxy)phenyl]ethyl]phenoxy]methyl]oxirane; and
(ad) 2-[2,2-bis(oxiran-2-ylmethoxymethyl)butoxymethyl]oxirane.

Monomers having acrylate functional groups may comprise from one to four (e.g. 1, 2 or 3) acrylate functional groups per monomeric unit. There is no particular limitation on the structure of the monomeric unit, which may comprise one or more structural units selected from linear or branched aliphatic, cycloaliphatic and aromatic. As will be appreciated, the monomers may be substituted by further functional groups (e.g. OH, halo (e.g. F, Br, Cl, I) and the like).

Examples of suitable monomers having acrylate functional groups may include, but are not limited to:
(ae) methyl methacrylate;
(af) 4-prop-2-enoyloxybutyl prop-2-enoate;
(ag) 2,2-bis(prop-2-enoyloxymethyl)butyl prop-2-enoate; and
(ah) 6-[4-[1-methyl-1-[4-(4-oxohex-5-enoxy)phenyl]ethyl]phenoxy]hex-1-en-3-one.

Monomers having thiolene functional groups may comprise from one to four (e.g. 1, 2 or 3) thiolene functional groups per monomeric unit. There is no particular limitation on the structure of the monomeric unit, which may comprise one or more structural units selected from linear or branched aliphatic, cycloaliphatic and aromatic. As will be appreciated, the monomers may be substituted by further functional groups (e.g. OH, halo (e.g. F, Br, Cl, I) and the like).

Examples of suitable monomers having thiolene functional groups may include, but are not limited to:
(ai) hexane-1,6-dithiol;
(aj) [4-(sulfanylmethyl)phenyl]methanethiol; and
(ak) 6,6-bis(3-oxo-5-sulfanyl-pentyl)-1,11-bis(sulfanyl)undecane-3,9-dione.

Particular examples of photopolymerizable monomers that may be mentioned in embodiments herein include, but are not limited to the following list:
(bi) epoxycyclohexylmethyl-3′,4′-epoxycyclohexane carboxylate;
(bii) bis(oxiran-2-ylmethyl) cyclohexane-1,2-dicarboxylate;
(biii) 2-[[4-[1-methyl-1-[4-(oxiran-2-ylmethoxy)phenyl]ethyl]phenoxy]methyl]oxirane;
(biv) 2-[2,2-bis(oxiran-2-ylmethoxymethyl)butoxymethyl]oxirane;
(bv) methyl methacrylate;
(bvi) 4-prop-2-enoyloxybutyl prop-2-enoate;
(bvii) 2,2-bis(prop-2-enoyloxymethyl)butyl prop-2-enoate;
(bix) 6-[4-[1-methyl-1-[4-(4-oxohex-5-enoxy)phenyl]ethyl]phenoxy]hex-1-en-3-one;
(bx) hexane-1,6-dithiol;
(bxi) [4-(sulfanylmethyl)phenyl]methanethiol; and
(bxii) 6,6-bis(3-oxo-5-sulfanyl-pentyl)-1,11-bis(sulfanyl)undecane-3,9-dione.

More particularly, the at least one photopolymerizable monomer may be a monomer selected from one or more of the following list:
(ci) epoxycyclohexylmethyl-3′,4′-epoxycyclohexane carboxylate;
(cii) bis(oxiran-2-ylmethyl) cyclohexane-1,2-dicarboxylate;
(ciii) 2-[[4-[1-methyl-1-[4-(oxiran-2-ylmethoxy)phenyl]ethyl]phenoxy]methyl]oxirane;
(civ) 2-[2,2-bis(oxiran-2-ylmethoxymethyl)butoxymethyl]oxirane;
(cv) methyl methacrylate;
(cvi) 4-prop-2-enoyloxybutyl prop-2-enoate;
(cvii) 2,2-bis(prop-2-enoyloxymethyl)butyl prop-2-enoate; and
(cviii) 6-[4-[1-methyl-1-[4-(4-oxohex-5-enoxy)phenyl]ethyl]phenoxy]hex-1-en-3-one,
   optionally wherein the at least one photopolymerizable monomer is one or both of epoxycyclohexylmethyl-3′,4′-epoxycyclohexane carboxylate and methyl methacrylate (e.g. the at least one photopolymerizable monomer is epoxycyclohexylmethyl-3′,4′-epoxycyclohexane carboxylate).

The formulations disclosed herein may also include one or more of the following components as additives:
(ai) a co-initiator;
(aii) a co-sensitizer;
(aiii) a photostabilizer;
(aiv) an inhibitor
(av) a rheology modifier; and
(avi) a tackifier.

Co-initiators and co-sensitisers that may be used herein include, but are not limited to silanes, amines and combinations thereof. Examples of silane co-initiators that may be mentioned herein include, but are not limited to 3-aminopropyl triethoxysilane (APTES), trichlorosilane (SiHCl₃), tetramethylsilane (Si(CH₃)₄), tetraethoxysilane (Si(OC₂H₅)₄), and combinations thereof. Examples of amine co-initiators that may be mentioned herein include, but are not limited to triethylamine, trimethylamine, aniline, triethanolamine, phenylamine and combinations thereof. For example, amine co-initiators that may be used herein include, but are not limited to triethylamine, trimethylamine and combinations thereof.

Photostabilisers that may be used herein include, but are not limited to pigments, UV absorbers, hindered amines, phenolic antioxidants, metal chelates and combinations thereof. Examples of pigment photostablilisers that may be mentioned herein include, but are not limited to chromium oxide, oxide hydroxide, sulfide, silicate, sulfate, or carbonate, anthocyanins, chlorophyll and combinations thereof. Examples of UV absorber photostablilisers that may be mentioned herein include, but are not limited to benzophenones and benzotriazoles. Examples of hindered amine photostablilisers that may be mentioned herein include, but are not limited to tetramethylpiperidine and derivatives thereof. Examples of metal chelate photostablilisers that may be mentioned herein include, but are not limited to nickel chelates and iron chelates and combinations thereof that are known as photostablilisers.

Inhibitors that may be used herein include, but are not limited to hydroquinones, methylether hydroquinone (MEHQ), tert-butyl hydroquinone (TBHQ) and combinations thereof.

Rheology modifiers that may be used herein include, but are not limited to organo clays, montmorillonite (mmt) clays, talc, silicas, aluminates, zirconates, bentonites, hectonites, calcium sulfonate, organic rheology modifiers and combinations thereof. Organic rheology modifiers include but are not limited to reactive diluents, polyamides, polyureas, micellar structures, surfactants, flocculants, dispersing aids and combinations thereof.

Tackifiers that may be used herein include, but are not limited to 2-methyl 2-butene, cyclopentadiene, ethylene glycol ester, methyl ester, limonene, gum rosin, wood rosin and combinations thereof.

While it is possible to provide the formulation as a single mixture, there may be situations (e.g. when dealing with FRPCP formulations) when it is better to provide the formulation as two separate formulations that can be mixed together shortly before use. Thus, in a further aspect of the invention there is provided a kit of parts comprising:
(A) a first formulation comprising a hybrid composite material as described hereinbefore and a first portion of at least one photopolymerizable monomer; and
(B) a second formulation comprising a second portion of the at least one photopolymerizable monomer and one or both of a free radical photoinitiator and an oxidizable radical co-producer.

As noted above, the above arrangement may be particularly useful when dealing with a FRPCP system, as half of the required monomers may be mixed with the hybrid composite and the cationic photoinitiators, while the other half of the required monomers may be mixed with the free radical photoinitiator and/or oxidizable radical co-producer. Then, these two mixtures are mixed together and exposed to light to generate the desired final cured product.

Apart from the separation of the components into a first and second formulation (thereby potentially resulting in differing amounts/ratios in the first and second formulations as separate entities relative to that in the full formulation, which is the combination of the first and second formulations), the kit of parts is otherwise identical to the disclosed “full” formulations above. As such, a discussion of the various components will not be mentioned again here for the sake of brevity.

In embodiments of the kit of parts where the overall formulation may include a cationic photoinitiator, then the cationic photoinitiator will be present as part of the first formulation, thereby separating it from the free radical photoinitiator and/or the oxidizable radical co-producer.

In specific embodiments of the kits of parts, there may be disclosed a FRP kit of parts and a FRPCP kit of parts.

The FRPCP kit of parts may be formed from:
a first formulation comprising a hybrid composite material as described hereinbefore, a cationic photoinitiator and a first portion of at least one photopolymerizable monomer; and
a second formulation comprising a second portion of the at least one photopolymerizable monomer and one or both of a free radical photoinitiator and an oxidizable radical co-producer.

More particularly, the FRPCP kit of parts may relate to a kit suitable for use with monomers comprising epoxy/cyclohexane oxide/oxetane and epoxide cyclic oxide containing groups.

Such a kit of parts may use:
Formulation 1:
   monomers of epoxy, epoxide cyclic oxide ring containing molecules such as cyclohexane oxide (CHO), oxetane, and mixtures thereof;
   a hybrid composite material; and
   a cationic photoinititator; and
Formulation 2:
   monomers of epoxy, epoxide cyclic oxide ring containing molecules such as cyclohexane oxide (CHO), oxetane, and mixtures thereof; and
   a free radical photoinitiator and/or an oxidizable radical co-producer.

The FRP kit of parts may be formed from:
a first formulation comprising a hybrid composite material as described hereinbefore, a first portion of at least one photopolymerizable monomer, and, optionally, a cationic photoinitiator; and
a second formulation comprising a second portion of the at least one photopolymerizable monomer and one or both of a free radical photoinitiator and an oxidizable radical co-producer.

More particularly, the FRP kit of parts may relate to a kit suitable for use with monomers comprising acrylate, methacrylate or thiolene containing groups. Such a kit of parts may use:
Formulation 1:
   monomers of acrylate, methacrylate or thiolene containing molecules, and mixtures thereof;
   a hybrid composite material; and
   (optionally) a cationic photoinititator; and
Formulation 2:
   acrylate, methacrylate or thiolene containing molecules, and mixtures thereof; and
   a free radical photoinitiator and/or an oxidizable radical co-producer.

In the kits of parts mentioned herein:
the amount of the free radical photoinitiator, if present, may be from 0.1 to 5 wt % of the total weight obtained by the combination of the first and second formulations; and
the total amount of the oxidizable radical co-producer in the second formulation, if present, is from 0.2 to 10 wt %, such that it provides from 0.1 to 5 wt % of the total weight obtained by the combination of the first and second formulations; and
when a cationic photoinitiator is present, it forms from 0.1 to 5 wt % of the total weight of the combination of the first and second formulations.

Also disclosed herein is a method of of initiating and/or sensitizing photopolymerisation, comprising:
(gi) mixing a hybrid composite material as described hereinbefore with a composition comprising:
   at least one photopolymerizable monomer; and
   one or both of a free radical photoinitiator and an oxidizable radical co-producer to form a mixture; and
(gii) exposing the mixture to a light in order to provide a polymer product.

The mixture mentioned above in the method may correspond to the “full” formulation discussed hereinbefore. As such, the variations and combinations discussed above will not be repeated here for the sake of brevity. As will be appreciated, the mixture may be provided as a fully-formed “full” formulation as discussed above or it may be formed by the combination of a first and a second formulation according to the kits of parts disclosed above too. For the avoidance of doubt, the method above may make use of formulations that incorporate a cationic photoinitiator.

Any suitable wavelength of light may be used in the method. For example, the wavelength of the light may be from 250 to 1,200 nm, such as from 320 to 420 nm.

The formulations and method disclosed herein may be particularly useful in additive manufacture. As such, there is also disclosed a method of additive manufacture, the method comprising the steps of:
(hi) providing a mixture comprising:
   a hybrid composite material as described in the first aspect of the invention;
   at least one photopolymerizable monomer; and one or both of a free radical photoinitiator and an oxidizable radical co-producer;
(hii) forming a layer using the mixture according to a design;
(hiii) subjecting the layer to light to provide a polymer; and
(hiv) repeating steps (hii) and (hiii) until the desired design is complete.

Again, the mixture above in the method may correspond to the “full” formulation discussed hereinbefore. As such, the variations and combinations discussed above will not be repeated here for the sake of brevity. As will be appreciated, the mixture may be provided as a fully-formed “full” formulation as discussed above or it may be formed by the combination of a first and a second formulation according to the kits of parts disclosed above too. It may also use the same wavelengths of light as discussed above. For the avoidance of doubt, the method above may make use of formulations that incorporate a cationic photoinitiator.

As noted above, the wavelength of the light used in the method may be from 250 to 1,200 nm. Thus, as will be appreciated, the semiconducting material may be selected to be a material that can absorb light within this wavelength range. In particular embodiments mentioned herein, the organic semiconducting material may absorb wavelength(s) analogous to those typically used by 3D printer light sources. That is, the organic semiconducting material may absorb light in the UVA region (i.e. from 320 to 420 nm) for applicability in conventional stereolithographic apparatus (SLA) and digital light projection (DLP) technologies. Nonetheless, for self-built/commercial custom built direct writing machines that can be coupled with light sources having varying wavelengths for 3D printing, the organic semiconducting material can be selected to be a material with a suitable wavelength to match the selected light source. Such a selection can be readily made by a person skilled in the field.

Without wishing to be bound by theory, it is believed that in the hybrid composite material (e.g. PDA/MWCNT nanohybrid system), the conductive material (e.g. the carbon nanotube) acts as an electron sink preventing the chance of charge recombination leading to higher performance. This effect was observed with a conductive material (e.g. MWCNT) loading up to 0.5 wt %. The results show a unique advantage associated with the current invention, as the incorporation of a light absorbing/blocking nanofillers does not result in a reduced conversion speed in the light polymerization of monomers, such as epoxy. This effect is important in improving the mechanical properties of the resulting polymer without compromising on polymer curing speed and degree of monomer conversion in applications such as polymer nanocomposites, nanocomposites, nano-adhesives and more significantly in stereolithographic and ink jetting processes in polymer additive manufacturing. In addition, it is believed that the inclusion of an organic semiconducting material (e.g. the PDA component) in the hybrid composite material results in a polymeric product that is highly multi-surface compatible and increases the surface wettability of the nanocomposite (e.g. epoxy) resin on surfaces such as glass and even PTFE. This is a highly desirable property in coatings, adhesives and polymer printing.

As will be appreciated, the hybrid composite material disclosed herein may be formed by:
ba) dispersing a conductive material in a solution;
bb) adding a precursor of an organic semiconducting material to the solution; and
bc) separating the formed hybrid composite from the remaining solution.

The semiconducting material may be as described hereinbefore. The solution may be an aqueous basic solution, for example, having a pH of 8-9. The solution may be a buffer solution.

Alternatively, the solution may be an organic solvent.

### EXAMPLES

### Materials

Pristine and acid-functionalized MWCNT with 99% purity, and amine modified MWCNT-NH₂ were purchased from Cheap Tubes Inc. The tubes have an outer diameter of 13-18 nm, inner diameter of 4 nm and length of 1-12 μm. The MWCNT-COOH contains 2.6% of COOH. Hydrochloric acid (HCl), DA HCl, tris(hydroxymethyl)aminomethane (>99%) (Tris), ECC, commercial type I photoinitiator (PI) Irgacure 819 (BAPO), diphenyliodonium hexafluorophosphate (Iod), 9-vinylcarbazole (NVK), isobornyl acrylate (IBOA), BADA, methylene blue (MB) and analytical grade ethanol were purchased from Sigma-Aldrich. Gallium doped zinc oxide (GZO) (10 mol % doped, 10-20 nm, 20 wt. % suspension in water/MEK) was purchased from Chemikalie. Antimony doped tin oxide (ATO) (10 mol % doped, 10 nm, 40 wt. % suspension in water/ethanol) nanoparticles were obtained from NanoMaterials Technology. The nanoparticles were filtered and freeze dried before use to remove moisture. All other solvents used were technical grade. All materials were used as received.

### Analytical Techniques

### Thermogravimetric Analysis (TGA)

TGA was performed with TA Instruments TGA Q500 in air and a heating ramp of 10° C./min.

### Differential Scanning Calorimetry (DSC)

DSC was carried out with TA Instruments DSC Q10 under N₂ flow between 30° C. to 200° C. with a heating ramp of 10° C./min.

### Secondary Electron Imaging

SEI were obtained from JEOL JSM 6360, at an accelerating voltage of 5 kV or from JEOL FESEM 7600F, at an accelerating voltage of 1 or 5 kV.

### Transmission Electron Microscopy (TEM)

TEM was carried out with JEOL JEM-1400 operated at 100 kV or with Carl Zeiss Libra 120 Plus operated at 120 kV.

### Microscopy

Microscopy samples were prepared from redispersed PDA NP or PDA/MWCNT or PDA/GZO suspended in deionised (DI) water and dropped onto copper grids or silicon wafer, and dried in ambient conditions.

### Ultraviolet-Visible (UV-Vis) Spectrophotometry

UV-Vis spectra were recorded with PerkinElmer Lambda950 UV-Vis-NIR spectrophotometer.

### Fourier Transform Infrared Spectroscopy (FTIR)

FTIR was carried out on epoxy resins on KBr pellet irradiated by a UV-flood lamp (Incure F200P) with a 600 Watt metal halide lamp, an irradiance of 18 mW/cm² and exposure wavelength in the UVA (315-400 nm) region. 0.1 mm thickness of film was applied by drawing between spacers.

### Photoluminescence (PL) Spectroscopy

PL spectra were obtained using Agilent Technologies Cary Eclipse Fluorescence Spectrophotometer at room temperature (RT) with measurement in the wavelength range of 300-700 nm. PL was analyzed by excitation of the nanoparticles and nanohybrids.

### Contact Angle Measurements

Contact angle measurements were carried out by the sessile drop method with a DataPhysics OCA 15Pro Contact Angle measurement equipment.

### Energy-Dispersive X-Ray Spectroscopy (EDX)

EDX was carried out with INCA—XAct 10 mm².

### Differential Photocalorimetry (DPC)

DPC was performed with a TA Instruments DSC 2920 Differential Scanning Calorimeter equipped with a photo calorimetric accessory. Hg lamp equipped with a filter of cutoff wavelength <290 nm was used with an irradiation intensity of 18 mW/cm² to cure the resin (effective exposure between 290-660 nm). To stabilize the measurement system, the run sequence was started 1 min prior to sample irradiation through the shutter opening.

### Example 1. PDA Surface Modification on MWCNTs and Synthesis of PDA NP

### PDA Surface Modification on MWCNTs

MWCNTs were covalently modified with PDA via surface oxidative polymerization of DA in the presence of —COOH surface groups on MWCNT as described in Subramanian, A. S. et al., Polymer 2016, 82, 285-294. Briefly, the acid modified MWCNTs were dispersed in 0.01 M Tris HCl buffer solution (pH=8.5, 0.5 mg/mL), and subjected to tip sonication in an ice bath, followed by the addition of DA HCl with 1:0.5 MWCNT to DA ratio. The mixture was stirred at RT for 24 h. Then, the modified MWCNTs were filtered and washed. Agglomerated MWCNTs were removed by centrifugation and the supernatant was filtered and freeze dried prior to use. The amount of the PDA coating on the MWCNT was found to be 20 wt % by TGA and thus, the covalently modified PDA/MWCNT nanohybrids were termed as PDA20/MWCNT80.

### PDA NP

PDA NP were synthesized by following the protocol above except in DI water with DA (1 mg/mL) or 20% v/v ethanol (in water) solution with DA (1 mg/mL), and in the absence of MWCNTs. The resulting nanoparticles were washed and centrifuged thrice in water. The product was resuspended for microscopy sample preparation and freeze dried prior to use in polymerization study.

### Results and Discussion

The PDA surface modification step was altered to improve yield through longer ultrasonic treatment of raw MWCNT before the modification process. Through reduced centrifugation speed from 3000 rpm to 5 min at 500 rpm, large agglomerations were removed.

PDA is generally synthesized in water and coated on substrate surfaces to modify its characteristics. The PDA NP synthesized in 100% DI water showed different morphology from the PDA NP synthesized in 20% v/v ethanol solution. The preparation of PDA NP from the mixed solvent medium gave better control in shape regularity, surface smoothness and size distribution as seen from the SEI in FIG. 1a-b.

The synthesis of PDA NP had been reported previously, and the polymerization of DA in water had been deemed to be too fast, resulting in polydisperse PDA NP with broad particle size distribution and less uniform shape control. With mixed solvent medium, the DA polymerization reaction rate takes place in a more controlled manner as explained by chemical equilibrium position shift (Jiang, X., Wang, Y. & Li, M., Sci. Rep. 2014, 4, 6070). Furthermore, the particle size is determined by the quantity of DA monomers in the reaction medium (Kohri, M. et al., J. Mater. Chem. C 2015, 3, 720-724).

Particle size in the range of 200-250 nm was targeted here in order to achieve comparable surface area for the PDA/MWCNT nanohybrids to ensure fair comparison in its photosensitive application in the epoxy polymerization study. In order to maintain surface uniformity with the PDA coated MWCNTs, the PDA NP synthesized from DI water were used for all photocuring and optical characterization studies in the following examples.

### Comparative Example 1. Colloidal Stability of PDA/MWCNT and Pristine MWCNT

### Colloid Stability

1 mg/mL or 5 mg/mL of one of the materials selected from PDA/MWCNT (prepared in Example 1), pristine MWCNT, commercial acid modified MWCNT-COOH and commercial amine modified MWCNT-NH₂ (1 or 5 mg/mL) was added to DI water, followed by sonication in an ultrasonic bath for 10 min. The reaction mixture was left to stand in the rack for 10 min, 24 h or 30 days.

### Results and Discussion

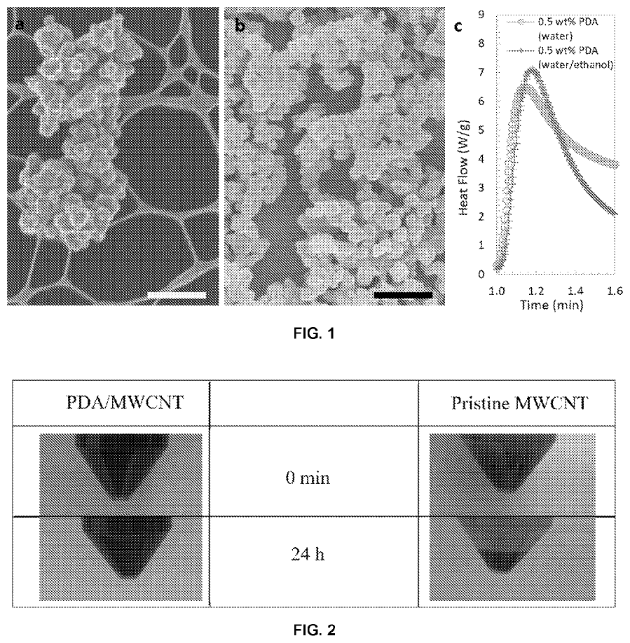

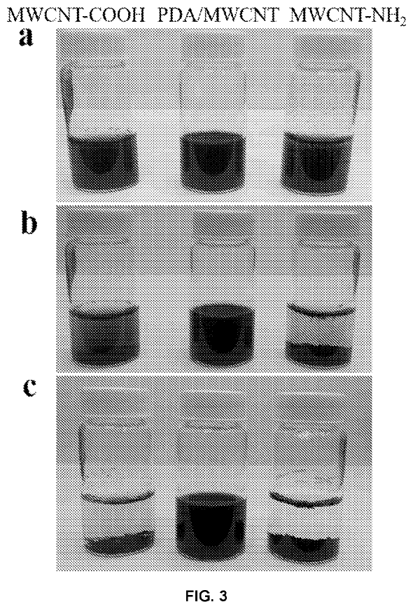

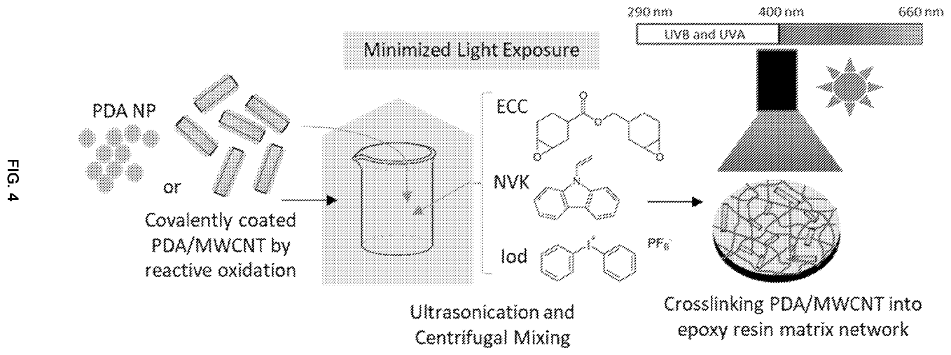

The PDA/MWCNT dispersed aqueous medium showed visible colloidal stability over 0 min, 10 min, 24 h and 30 days, as opposed to sedimentation in the pristine MWCNT and commercial acid modified MWCNT-COOH and commercial amine modified MWCNT-NH₂ (FIG. 2-3).

### Example 2. Preparation and Photocuring of PDA/MWCNT Photoreactive Resins

### Preparation of PDA/MWCNT Photoreactive Resins

One of the materials selected from PDA NP (prepared in Example 1), PDA/MWCNT (prepared in Example 1) and IRGACURE 819 (BAPO) was mixed with Iod PIs into half of the calculated amount of ECE monomer on a benchtop stirrer. The other half of ECC monomer was mixed with NVK and stirred. After 20 mi, the two parts of ECC monomer were combined to give ECC and P % and/or photosensitizer (PS, PDA NP or PDA/MWCNT or IRGACURE 819 (BAPO)) balanced with NVK/Iod at (3 wt %/2 wt %). The mixture was sonicated for 5 m at 30° C., and mixed in a planetary centrifugal mixer at 2000 rpm for 5 min. The labels and their respective system are described in Table 1.

TABLE 1
Labels and their respective system.

| Label | System comprising |
|---|---|
| ECC/lod | lod (2 wt %) |
| | ECC monomer |
| ECC/lod/NVK | NVK/lod (3 wt %/2 wt %) |
| | ECC monomer |
| 0.125 wt % or 0.5 wt % | NVK/lod (3 wt %/2 wt %) |
| or 1.0 wt % PDA | PDA (0.125 wt % or 0.5 wt % |
| | or 1.0 wt %) |
| | ECC monomer |
| 0.125 wt % PDA + 0.5 wt % | NVK/lod (3 wt %/2 wt %) |
| MWCNT | PDA (0.125 wt %) |
| | Pristine MWCNTs (0.5 wt %) |
| | ECC monomer |
| 0.5 wt % MWCNT | NVK/lod (3 wt %/2 wt %) |
| | Pristine MWCNTs (0.5 wt %) |
| | ECC monomer |
| 0.125 wt % or 0.625 wt % | NVK/lod (3 wt %/2 wt %) |
| or 1.25 wt % | Covalently bonded nanohybrids |
| (PDA20/MWCNT80) | comprising 20 wt % PDA and 80 wt % |
| | MWCNTs (0.125 wt % or 0.625 wt % or |
| | 1.25 wt %) |
| | ECC monomer |
| 0.5 wt % BAPO | NVK/lod (3 wt %/2 wt %) |
| | BAPO (0.5 wt %) |
| | ECC monomer |
| 0.5 wt % BAPO + | NVK/lod (3 wt %/2 wt %) |
| 0.5 wt % MWCNT | BAPO (0.5 wt %) |
| | Pristine MWCNTs (0.5 wt %) |
| | ECC monomer |

The wt % indicated above is based on the total weight of each system.

### Photocuring of Resins

An appropriate consistent amount of resin (3+/−0.1 mg) was weighed on a standard Al pan. Crosslinking of the epoxy resin monomers containing various initiator/sensitizers was monitored by DPC. The preparation of the photopolymerization resins is also shown in FIG. 4, with the nanostructured additives and other chemical additives suitably dispersed/dissolved in the monomer resin under feasibly darkened conditions and exposed in UVB (280-315 nm), UVA (315-400 nm), near UV and visible light (400-660 nm).

### Results and Discussion

The processability of the MWCNTs in the resins was improved by grinding the freeze-dried samples before suspension in monomer resins and use of tip sonicator to improve dispersion.

### Example 3. Epoxy Polymerization with Photoactive PDA/MWCNT and PDA Traced by DPC

The reactivity of the epoxide largely depends on the extent of strain experienced by the ring monomer (Crivello, J. V. & Varlemann, U., J. Polym. Sci. A Polym. Chem. 1995, 33, 2463-2471). In cyclic epoxies such as ECC, the ring is highly strained, making it more reactive than linear molecule epoxy such as diglycidyl ether of bisphenol A (DGEBA). Further, DGEBA has neighboring oxygen atoms that stabilize the intermediate cationic species thus retarding chain growth (dell'Erba, I. E., Arenas, G. F. & Schroeder, W. F., Polymer 2016, 83, 172-181). As ECC is more reactive, it is the most commonly selected epoxy model molecule for photopolymerization studies to evaluate the influence of PI, PS, nanofiller, irradiation wavelength on the reaction rates and DOC. Further, although homopolymerization of the single ECC monomer is only expected to give a relatively brittle polymer due to the short chain length available between the crosslinking point, its anticipated relative reactivity and extremely suitable low viscosity of 400 mPa·s (or cP) at 25° C. makes ECC an attractive monomer to study PI parameters for potential applications such as stereolithography resins and coatings. Hence, ECC was used in the following examples.

### Photocalorimetry

The heat flow recorded from DPC with the progression of the photopolymerization was used to measure the time taken to reach exothermic peak maximum, to calculate the enthalpy change of reaction and final DOC, and to trace the conversion rate. In the isothermal photocuring process, the degree of final conversion (in %) of the reactive epoxide groups was calculated from the heat released up to time t, according to equation 1. The enthalpy change of reaction (ΔHₜ) measured upon light exposure is divided by the total exothermic heat of reaction (ΔH_{T}) for the complete polymerization of the epoxide groups in the resin system as measured from DSC.

$$a , DOC = \frac{Δ {H}_{t}}{Δ {H}_{T}} \times 100 \% \qquad ( 1 )$$

ΔHₜ values (in J/g) were obtained by integrating the peak exothermic curve using a sigmoidal horizontal as the baseline. ΔH_{T} value was obtained by integrating the exothermic peak of thermal cured ECC epoxy resin, and was determined to be 451 J/g. This was close to the typical range reported in literature for latent curing of epoxy systems: 407 J/g (Corcione, C. E., Freuli, F. & Frigione, M., Materials 2014, 7, 6832-6842); and 423-484 J/g (Wu, F., Zhou, X. & Yu, X., RSC Advances 2018, 8, 8248-8258). The conversion rate is directly proportional to reaction rate, that is the rate of heat flow with respect to time, at a constant temperature and is defined as given in equation (2),

$$da / dt = \frac{{dH}_{t} / ζ dt}{Δ {H}_{T}} \qquad ( 2 )$$

where dHₜ/dt is the measured heat flow at a constant temperature, in (W/g), (W=J/s).

### Results and Discussion

DPC run on the photosensitization of the 2 different types of nanoparticles in the FRPCP of ECC monomers revealed peak exotherm times of 1.15 min and 1.18 min for ECC resins containing 0.5 wt % PDA (water) and 0.5 wt % PDA (water/ethanol) as shown in FIG. 1c.

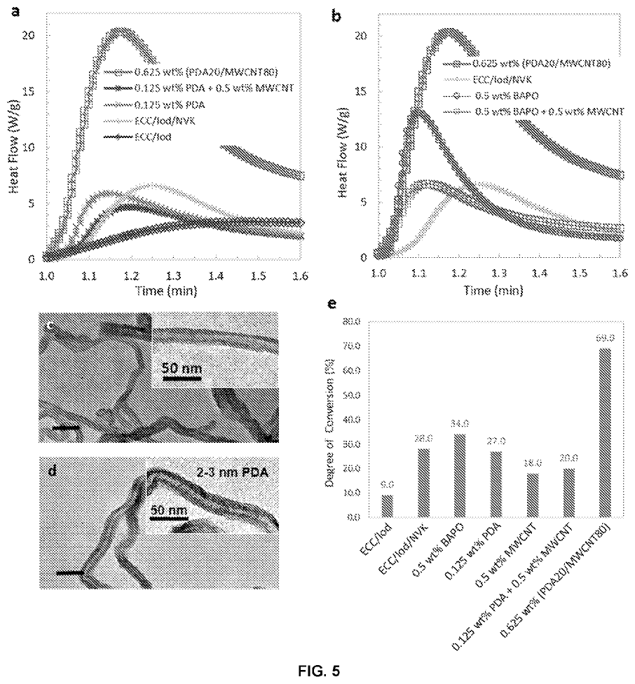

The heat flow curves for various photoinitiating and/or photosensitizing systems (PIS) with ECC monomer is given in FIGS. 5a-b and 6. The resin systems comprised of a PS/co-initiator, NVK/Iod (3 wt %/2 wt %) and were balanced with ECC monomer. On the other hand, the blank system comprised of NVK/Iod (3 wt %/2 wt %) only while the cationic system comprised of cationic Iod initiator (2 wt %) only. In FIG. 5a, same amount of carbon nanotubes (0.5 wt %) and/or same amount of PDA component (0.125 wt %) were used across the different filled systems. With the purely cationic initiating system (ECC/Iod), there was hardly any peak exotherm and polymerization as the monomer conversion was as low as 9% in the exposure wavelength of 290-660 nm. The cationic initiator, Iod, requires wavelength in the range 220-250 nm for activation for cationic polymerization. Hence, the PIS comprising PDA NP, PDA/MWCNT nanohybrids and NVK sensitizers were utilized for the FRPCP process, together with the Iod cationic initiator. The TEM images of pristine MWCNT before modification and the covalently modified (PDA20/MWCNT80) nanohybrids (comprising 20 wt % PDA component and 80 wt % MWCNT component) are shown in FIG. 5c-d.

With the incorporation of free radical initiators and sensitizers for the FRPCP process, the final conversion increased from 9% for the cationic system to beyond 30%. The most reactive and synergistic system was the combination of the cationic system with 0.625 wt % PDA20/MWCNT80 (of which the MWCNT component makes up 0.5 wt % and PDA 0.125 wt %) where the final conversion was calculated to be 69%. Compared to the neat ECC/Iod/NVK system which demonstrated a final conversion of 28%, the cationic system with 0.625 wt % PDA20/MWCNT80 has super efficiency in the photosensitization/co-initiation role (FIG. 5a, e). The modified PDA/MWCNT system with as low as 0.125 wt % PDA component showed much higher reactivity compared to 0.5 wt % of BAPO PI which showed 34% conversion (FIG. 5b, e). It was found that the addition of pristine MWCNT into the BAPO photoinitiating system to fabricate nanocomposites slowed down the reaction.

The FRPCP rate (proportional to heat flow) was also enhanced with PDA/MWCNT, with the maximum rate of conversion (peak max) attained at 10.2 s compared to 18 s for neat PIS resin (ECC/Iod/NVK). Table 2 shows the exothermic peak maximum times, heat flow values, the DOC, and enthalpy of polymerization (ΔHₜ) at time of complete reaction at the given exposure conditions and PIS together with ECC and Iod/NVK (2 wt %/3 wt %). Interestingly, this synergistic effect was only observed with surface modified MWCNT with PDA, where PDA is in direct contact with and covalently bonded to MWCNT. This synergistic effect was absent in the PIS where the same amount of discrete PDA NP (0.125 wt %) and pristine MWCNT (0.5 wt %) were added to the ECC monomer resin. In fact, the rate of reaction was slower than the PIS comprising 0.125 wt % PDA NP.

TABLE 2
DPC of ECC resin with various FRPCP PIS upon UV-
Vis irradiation with (lod/NVK; 2 wt %/3 wt %) and
of (ECC/lod; 98 wt %/2 wt %) cationic system.

| | | | Peak Maximum | |
|---|---|---|---|---|
| | DOC | | Time | Heat |
| Sample | (%) | ΔH_{C}(J/g) | (s) | flow (W/g) |
| ^{a}ECC/Iod | 9.0 | 43.9 | 28.2 | 3.4 |
| ECC/Iod/NVK | 28.0 | 129.8 | 18.0 | 6.6 |
| ^{b} 0.125 wt % PDA | 27.0 | 122.2 | 9.0 | 5.9 |
| 0.5 wt % PDA | 30.0 | 135.1 | 9.0 | 6.5 |
| 1.0% wt % PDA | 25.0 | 113.3 | 7.2 | 6.9 |
| 0.5% wt % BAPO | 34.0 | 153.9 | 6.0 | 13.1 |
| ^{c}0.5 wt % BAPO + | 28.0 | 127.6 | 7.2 | 6.6 |
| 0.5 wt % MWCNT | | | | |
| ^{c}0.5% wt % MWCNT | 18.0 | 82.5 | 13.2 | 3.8 |
| ^{b, c} 0.125 wt % PDA + | 20.0 | 92.3 | 12.0 | 4.7 |
| 0.5 wt % MWCNT | | | | |
| ^{d} 0.125 wt % | 31.0 | 143.0 | 9.0 | 8.8 |
| (PDA20/MWCNT80) | | | | |
| ^{b} 0.625 wt % | 69.0 | 314.1 | 10.2 | 20.4 |
| (PDA20/MWCNT80) | | | | |
| ^{e} 1.25 wt % | 26.0 | 121.4 | 10.2 | 6.3 |
| (PDA20/MWCNT80) | | | | |

^{a}Purely cationic system, does not contain any free radical initiators/sensitizers
^{b} These systems contain equal amount of PDA component at 0.125 wt %
^{c}Refers to 0.5 wt % of pristine MWCNT
^{d} Contains 0.025 wt % PDA component and 0.1 wt % MWCNT component
^{e} Contains 0.25 wt % PDA component and 1.0 wt % MWCNT component
All the FRPCP resin systems contain (NVK/Iod) at (3 wt %/2 wt %) balanced with ECC

Comparing with literature, with the perovskite heterogeneous PI system, 30% conversion was observed with 25 s exposure time where the source intensity was higher at 100 mW/cm². Ag salts (Sangermano, M., Yagci, Y. & Rizza, G., Macromolecules 2007, 40, 8827-8829) or Au salt+Iodonium salt (Yagci, Y., Sangermano, M. & Rizza, G., Macromolecules 2008, 41, 7268-7270) were used to produce Ag and Au particles in situ during the redox processes set off upon illumination during the cationic polymerization initiation steps. ECC monomers had conversion of 35% with Ag salt at 50 s of UV irradiation and 70% conversion with Au/onium salt at 50 s of visible light irradiation. Visible light sensitive ketones such as thioxanthone, camphorquinone (Schroeder, W. F. et al., Polym. Int. 2013, 62, 1368-1376; Schroeder, W. F. et al., Polym. Adv. Technol. 2013, 24, 430-436; and Vitale, A. et al., Materials 2014, 7, 554-562) and anthraquinone types, have been used together with monomers that could act as hydrogen donors, where up to 69% conversion of epoxy had been observed at 50 s of illumination of 3.3 mW/cm² UV-Vis light λ above 300 nm (Crivello, J. V. & Sangermano, M., J. Polym. Sci. A Polym. Chem. 2001, 39, 343-356). Other systems explored were Titanocene/Iodonium salt with cyclohexene oxide (CHO) monomer (77% conversion @ 30 min, Degirmenci, M. et al., Polym. Bull. 2001, 46, 443-449) and Benzoyltrimethylgermane/Iodonium salt with CHO monomer (86% conversion @ 30 min, λ: 350-420 nm, Durmaz, Y. Y., Moszner, N. & Yagci, Y., Macromolecules 2008, 41, 6714-6718).

Here, some of the PDA NP and pristine MWCNT have random dynamic contact and electrostatic attraction is possible due to π-π stacking (Son, E. J. et al., J. Mater. Chem. A 2016, 4, 11179-11202). However, in the PDA/MWCNT system, the contact between the bioconjugated semiconducting PDA and conductor MWCNT creates a heterojunction and photoinduced electron transfer (PET) that gives its synergistic advantage in driving the FRPCP of the epoxy monomers. This is analogous to a previous study by Li et al. that reported on perovskite stabilized single walled CNTs forming type II heterojunction (characterized by photoemission spectroscopy), leading to excited state charge transfer upon illumination with enhanced transport of photoexcited holes and electrons by reduction of charge recombination (Li, F. et al., Adv. Mater. 2017, 29, 1602432). This is also analogous to PDA-TiO₂ binding that creates a charge transfer band where the catechol served as type II PSs forming charge transfer complexes that allow injection of electrons into the TiO₂ akin to p-n junction semiconductor solar cells (Son, E. J. et al., J. Mater. Chem. A 2016, 4, 11179-11202).

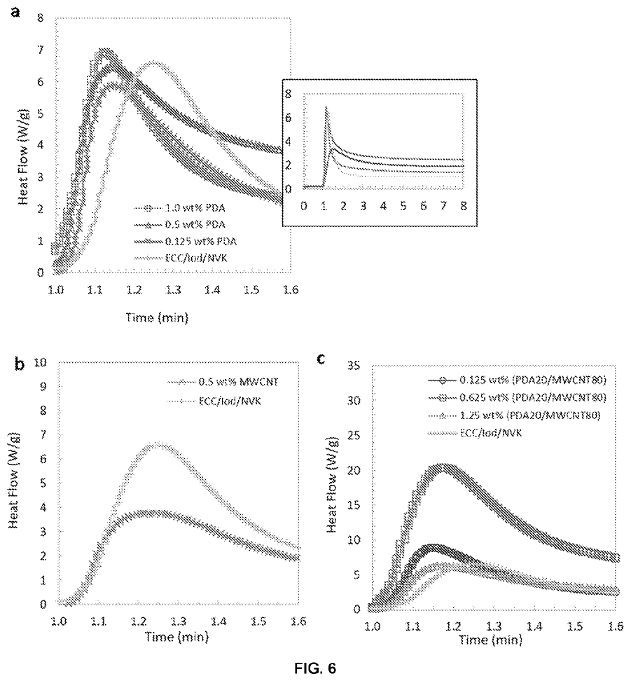

The addition of PDA NP alone improved the conversion marginally but improved peak maximum time from 18 s for NVK/Iod to 7.2-9 s for 1-0.125 wt % PDA. With 0.125 wt % PDA, the peak maximum heat flow was reduced compared to the neat system, but improved after increasing PDA content to 0.5 wt % onwards. These results suggest a change in mechanism and PDA is not merely a sensitizer to the Iod/NVK PIS. PDA improved the overall sensitivity of the PIS (in terms of the increased rate of conversion, FIG. 6a) due to its semiconducting nature and bioconjugated chemical structure akin to dye sensitization. This enhances its suitability for application in processes such as stereolithography to maintain the structural integrity of the printed part before complementation with offline thermal curing step.

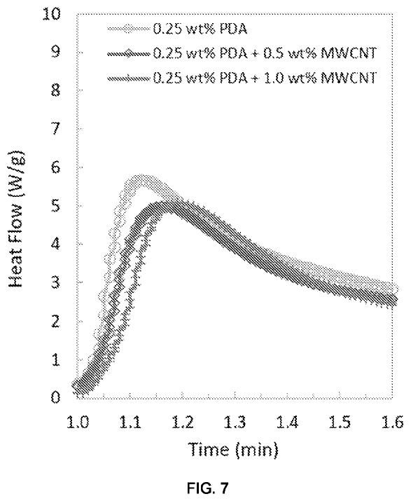

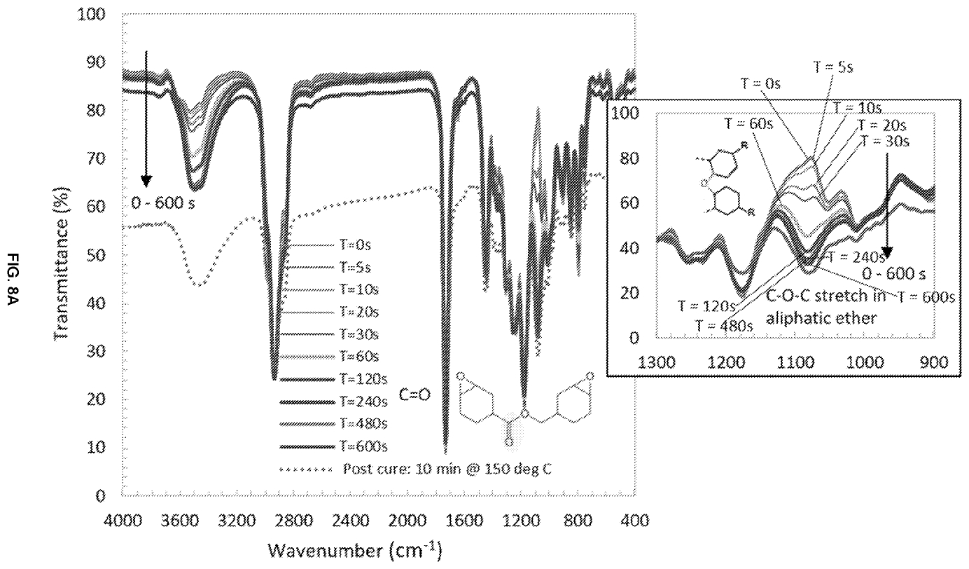

The 3-component system (PDA/hybrid+NVK+Iod) initiated the polymerization more efficiently than the 2-component system (NVK+Iod). With the neat NVK/Iod PIS, 28% conversion was recorded which however, dropped drastically to 18% upon addition of pristine MWCNT nanofillers. This could be due to light absorption and blockage preventing monomers in the lower layers of the film from receiving the irradiation (FIG. 6b). This was also found to be consistent in the 0.125 wt % PDA system (FIG. 5a) and 0.25 wt % PDA system (FIG. 7).

The effect of different concentration of the PDA20/MWCNT80 in the PIS is shown in FIG. 6c). Increasing the amount of the nanohybrid sensitizer/co-initiator increased the reaction speed till the weight content of MWCNT was 0.5 wt % (in 0.625 wt % PDA20/MWCNT80). At 1 wt % MWCNT equivalent (1.25 wt % PDA20/MWCNT80), the reactivity dropped drastically as the larger amount of MWCNTs block the light and the PDA/MWCNT nanohybrid was no longer effective as sensitizer/co-initiator in boosting the FRPCP process meaningfully.

### Example 4. DOC of MWCNTs Epoxy Resin Systems from FTIR Analysis

The MWCNTs epoxy resin systems prepared in Example 2 were taken for FTIR analysis to determine DOC.

DOC from FTIR Analysis

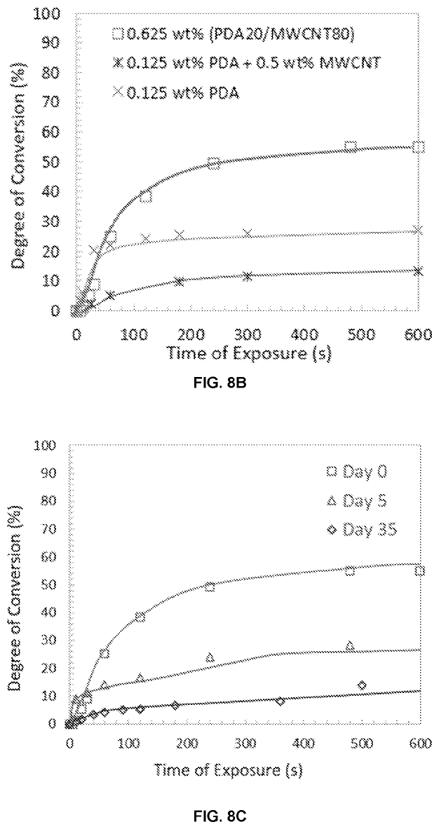

The conversion of the epoxide groups on the monomers could be calculated approximately quantitatively from the absorption peak height ratios between evolving functionality peak and constant functionality peak. The transmittance peak at 1731 cm⁻¹ representing the carbonyl group (C═O) on the epoxy backbone (FIG. 8a, Lee, E. H. & Kim, D. S. Polym. Polym. Compos. 2016, 24, 655-662) remained constant in the polymerization process. The transmittance peak at 1080 cm⁻¹ representing the aliphatic ether (—C—O—C—) group (Golaz, B. et al., Polymer 2012, 53, 2038-2048) was formed upon the opening of the epoxide monomer ring. The addition of the next epoxide monomer increased the characteristic band with light exposure time. The intensity of all the peaks at 1080 cm⁻¹ were normalized against the peak at 1731 cm⁻¹.

DOC was calculated from peak intensity ratio changes with respect to the exposure time from FTIR analysis using the following equation,

$$DOC = [ 1 \frac{{T}_{tn}^{1731} / {T}_{tn}^{1080}}{{T}_{t 0}^{173} / {T}_{t 0}^{1080}} ] \times 100 \% \qquad ( 3 )$$

Where T is the transmittance peak intensity value at tn (time of exposure) and at t0 (time of zero exposure), and at wavenumbers 1731 and 1080 cm⁻¹.

### Results and Discussion

The epoxy resin systems with the various PDA based sensitizers/co-initiators exposed to UVA irradiation under a metal halide lamp showed slower conversion as PDA has the lowest absorption in this range (FIG. 8b). However, the trend of PDA hybrids/nanoparticles of similar content and with pristine MWCNT was in agreement with the DPC results in Example 3, and further confirm that synergy was only possible with direct contact of PDA with MWCNT. Otherwise, the presence of the same amount of MWCNT (0.5 wt %) independently only reduced the conversion. It has to be noted that sometimes IR data does not correlate with DPC results (Kowalczyk, K. & Kowalczyk, A. Prog. Org. Coat. 2015, 89, 100-105).

### Example 5. UV-Vis Absorption and PL Spectroscopy

The materials prepared in Examples 1-2 were characterized by UV-Vis absorption and PL spectrometry.

### Results and Discussion

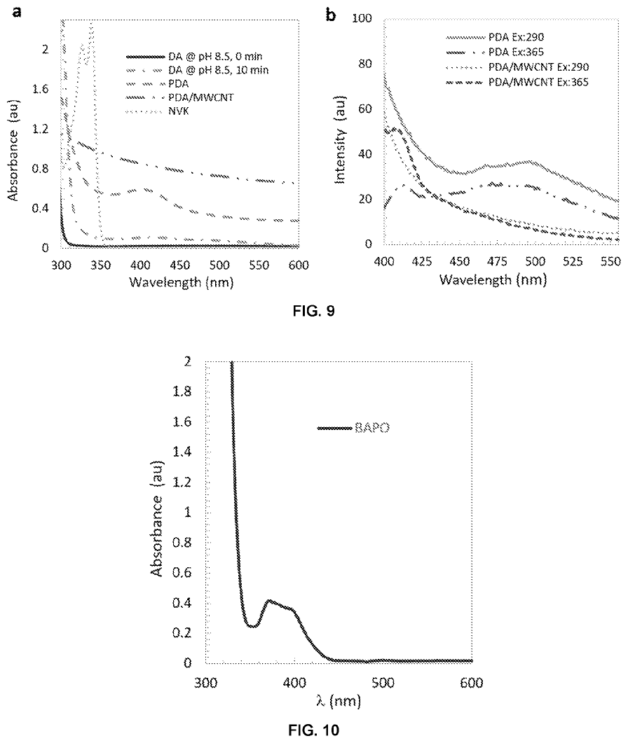

From the UV-Vis absorbance spectra, it was found that the PDA NP exhibited strong absorption below the mid UV region (<320 nm) and a slight hump between 390-440 nm, which was absent in the monomer DA spectrum. This served as a way to monitor the oxidative polymerization of DA monomers in the reaction media where the peak at 400 nm started to appear as fast as 10 min of reaction time at pH 8.5 (FIG. 9a).

The PDA modified MWCNT exhibited a broad spectrum of absorption in the range of analysis and NVK, the third component sensitizer/co-initiator in the 3-component PIS for FRPCP, showed strong absorption between 310 and 350 nm. Hence, all the components have suitable absorption ranges to play an active role in the photopolymerization of the ECC monomers in the UV-Vis and UVA illumination exposure ranges here. BAPO also showed absorption in the 350-420 nm range (FIG. 10).

Upon irradiation of the semiconducting material, photoexcitation occurs, and an electron get promoted from the valence band to conduction band, or from HOMO level to LUMO level in the case of PDA, giving rise to a ‘hole’ in the HOMO level. The excited electron LUMO level relaxes quickly in the range of 15-25 ps (Baer, D. & Thevuthasan, S., Characterization of Thin Films and Coatings, 2010) to the band edge by scattering, followed by recombination with the hole radiatively through photon emission or non-radiatively by transferring energy to phonons at impurity/defect/dopant traps. The emission spectra resulting from the recombination of charge carriers in semiconductors (Guan, S. et al., Top. Catal. 2018, 61, 1585-1590) give information about the electron hole movement in the particles upon excitation at a given wavelength suitably in the absorption range of the particles. From PL spectroscopy analysis, PDA exhibited a weak fluorescence (peak emission 440-550 nm) upon excitation by UV-Vis light at 290 nm and 365 nm. At these two excitation wavelengths, the fluorescence peak was found to be quenched in the PDA/MWCNT nanohybrids via PET (Qiang, W. et al., Chem. Sci. 2014, 5, 3018-3024), indicating suppression of charge recombination effect. Sheng et al., have also mentioned that photosensitized electron transfer on PDA surface upon illumination generates reactive radicals from excited PDA (Sheng, W. et al., Chem. Sci. 2015, 6, 2068-2073). Other researchers have also reported studies involving photo illumination to induce electron transfer from PDA (Son, E. J. et al., J. Mater. Chem. A 2016, 4, 11179-11202) and its nanohybrids with other materials such as TiO₂ (photogenerated electrons from PDA transferred to conduction band of TiO₂, Wang, C. et al., ACS Appl. Mater. Interfaces 2017, 9, 23687-23697; and Mao, W.-X. et al., Chem. Commun. 2016, 52, 7122-7125) and Cu₂O (Zhou, X. et al., J. Solid State Chem. 2017, 254, 55-61).

This explains the substantial performance enhancement (higher conversions, shorter peak exotherm times and conversion rate) of the PDA/MWCNT nanohybrid heterogeneous photoactive species in the photopolymerization of ECC monomers.

### Example 6. Nanocomposite Resin and Film Transmittance

The contact angles of the various MWCNTs prepared in Examples 1-2 were measured. In addition, the absorption spectra of the various MWCNTs mixed with the photopolymer resin and cured under UV-Vis light in Example 2 were recorded with an UV-Vis spectrometer.

### Results and Discussion

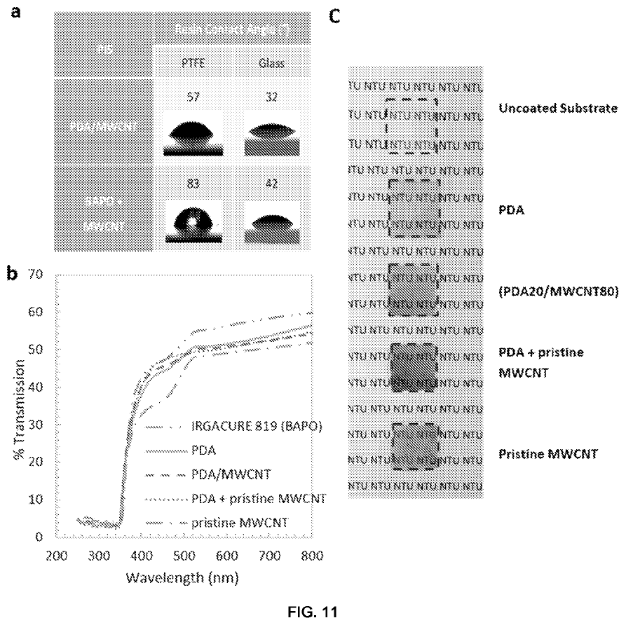

The contact angles of the ECC resins containing PDA/MWCNT (i.e., 0.625 wt % PDA20/MWCNT80) and commercial IRGACURE 819 (BAPO) with pristine MWCNT (i.e., 0.5 wt % BAPO+0.5 wt % MWCNT) on PTFE and glass substrates for ECC resins are given in FIG. 11a. The PDA surface modification on MWCNT allowed better wetting of the ECC resin and reduced contact angle made on both substrates compared to the commercial PI+pristine MWCNT containing resin.

The UV-Vis cured films were analyzed by UV-Vis spectroscopy for their transmittance (FIG. 11b). Above 400 nm, all the films exhibited transmittance comparable to the film containing commercial PI IRGACURE 819 (BAPO) except pristine MWCNT due to its poor dispersion. Therefore, other than the film containing pristine MWCNT, the transmittance is similar for all the other materials in the 350 to 500 nm range. However, the color of the PDA containing system became grey tinted due to the nature of PDA. PDA coating on the MWCNT enhanced the dispersion of the nanotubes in the ECC matrix thus allowing for better translucency compared to the poorly dispersed pristine MWCNT system and less well dispersed discrete PDA+pristine MWCNT system (FIG. 11c). The PDA/MWCNT showed 30% higher light transmission in the UV-Vis region and no visible agglomeration (FIG. 11b-c).

### Example 7. Cure Depth Evaluation in DLP Printing

### Cure Depth Evaluation in DLP Printing

Resin system: Commercial acrylate monomers (IBOA or BADA)
PS/co-initiator cum nanofiller: PDA20/MWCNT80 (prepared in Example 1)
Nanofiller: Pristine MWCNT, 0.5 wt % BAPO and either 0.625 wt % PDA20/MWCNT80 (prepared in Example 1) or 0.5 wt % pristine MWCNT were added to the resin system.

### Wavelength: 405 nm

Intensity: 11.20 mW/cm²

Two formulations of nanocomposite acrylate resins were prepared with 0.5 wt % PDA/MWCNT or 0.5 wt % pristine MWCNT.

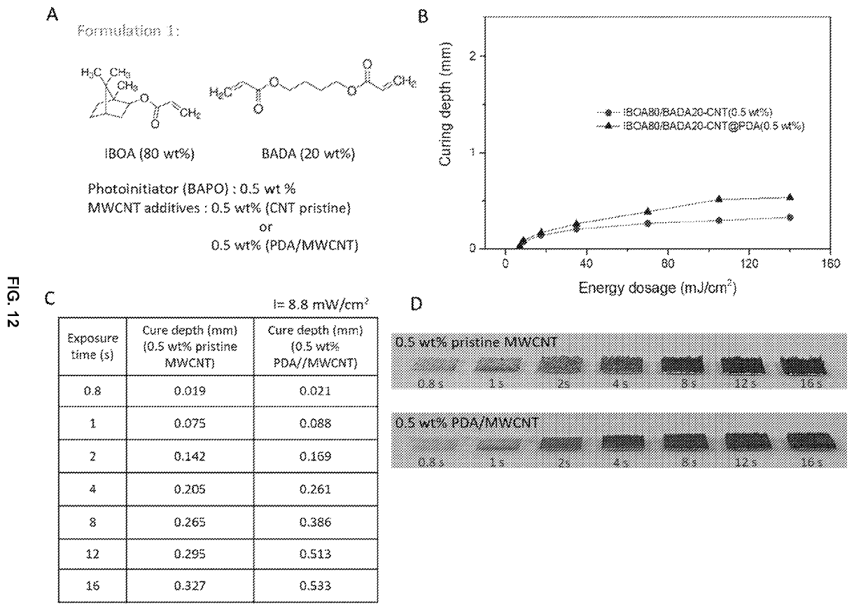

### Formulation 1 (FIG. 12a):

(IBOA/BADA wt ratio 80:20) at 99 wt %+BAPO 0.5 wt %+PDA/MWCNT 0.5 wt % or pristine MWCNT 0.5 wt %

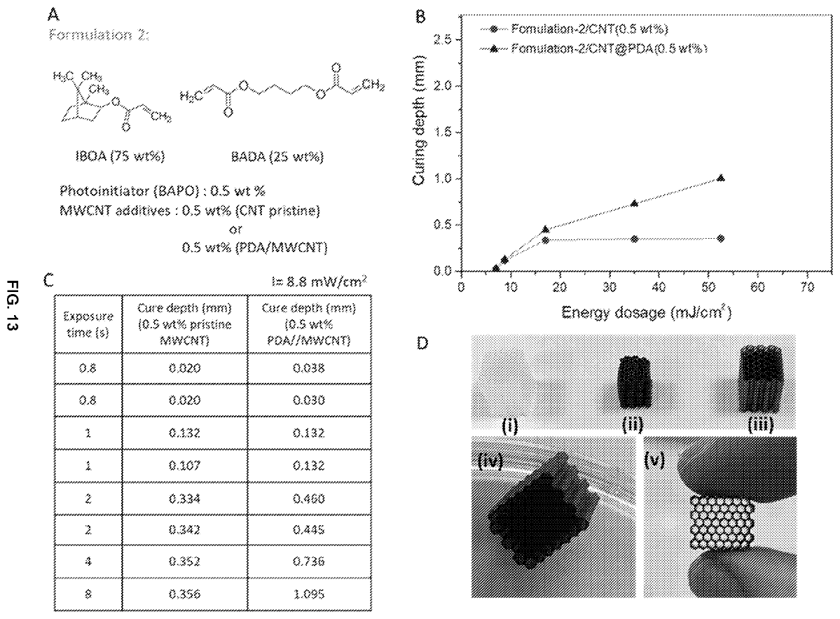

### Formulation 2 (FIG. 13a):

(IBOA/BADA wt ratio 75:25) at 99 wt %+BAPO 0.5 wt %+PDA/MWCNT 0.5 wt % or pristine MWCNT 0.5 wt %

DLP printing and cure depth measurement was carried out in a BMF microArch™ S140 printer with a light source wavelength of 405 nm. The cure depth was evaluated by curing the resin at the given exposure times at 405 nm with a light intensity of 11.20 mW/cm². The exposure times per layer used have to be reasonable for applicable processing time in industry scales, and sufficient to handle and process further by thermal postcuring. The light was projected upwards through a glass plate containing a well of excess resin for a fixed period. After exposure, the uncured resin was wiped off, leaving the cured sample. The resulting cured resin height was measured with a digital calliper. The values were plotted and the depth of penetration was calculated. Cure depth is given as,

Cd=Dp ln(E₀/Ec)

Where Cd is the cure depth (mm), E₀ is the energy dosage per area (mJ/cm²), Ec represents a “critical” energy dosage (mJ/cm²), and Dp is the depth of penetration of light source into the resin (mm).

E₀ is a function of the exposure time and power source irradiance intensity, and is given by

E₀=t×I

Where t=Time (s), and I=Irradiance intensity (mW/cm²).

### Results and Discussion

Since no nozzle is involved in this type of vat printing, there is no clogged nozzle.

For the acrylate system (Formulation 2) containing modified PDA/MWCNT, the surface of the cured tab appeared visibly finer and more uniformed than the cured tab containing pristine MWCNT (FIG. 12d). Further, the exposure time per layer was recorded at 1-2 s, which is comparable to commercial resins of the acrylate family at light intensity of 8.8 mW/cm². The modified PDA/MWCNT showed higher curing depth in both instances (FIG. 12b-c and FIG. 13b-c) compared with unmodified pristine MWCNT.

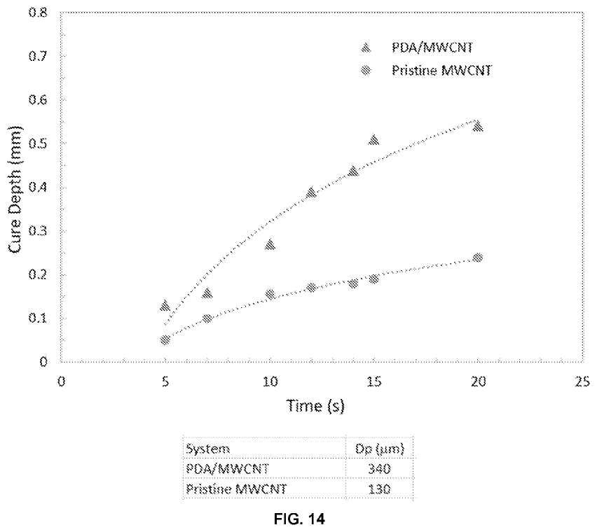

The cure depth of the acrylate resin system (Formulation 1) is shown in FIG. 14. With the use of PDA/MWCNT, the cure depth was increased by 80% and 125% at 10 s and 20 s exposure times, respectively, when compared to the pristine system in the nanocomposite resins. The MWCNT nanocomposite systems are expected to exhibit better mechanical properties with good dispersion of the nanofillers compared to their respective neat resins. The dispersion advantage of PDA/MWCNT had been evaluated by the inventors previously (Subramanian, A. S. et al., Polymer 2016, 82, 285-294).

PDA/MWCNT functions as a photoabsorber to limit the vertical curing apex/lateral overcure (that appear as flashes or burrs/striations on the printed part). Surface burrs were observed for the printed samples containing pristine MWCNT and the printed part itself was extremely soft. Generally, in DLP printing, a certain level of overcure print parameter is set to ensure sufficient curing of each layer before building the next layer on it. For 0.1 mm target layer thickness, the time required for 0.15 mm thickness cure (based on cure depth curve generated) was set for the print process for all 3 types of samples (pristine MWCNT, neat acrylate and PDA/MDCNT containing nanocomposite acrylate resins). However, the system containing pristine MWCNT failed to print. For pristine MWCNT, a longer exposure time (corresponding to 0.34 mm) than the target thickness cure time had to be utilized to enable printing. Despite that, the printed part was extremely soft and became deformed as further layers continued to be cured. The shrunken and distorted print is shown in (FIG. 13d(ii)). In the pristine MWCNT containing system, extensive light blocking effect led to poorer curing and conversion of the resin, leading to a misshapen appearance as the weakly cured layers were unable to support further layers being built.

The Dp of the optical energy into the resin represents the depth at which the irradiance becomes 1/e times that at the surface and this increased with the use of modified PDA/MWCNT compared to pristine MWCNT. This phenomenon could be explained by light blocking effect versus the radical formation upon illumination of the PDA/MWCNTs. Following the generation of radicals, the sensitization occurs in the modified MWCNT containing systems. The radical generation and light blocking effect are at interplay, thus the system with modified system showed better cure depth buildup as compared to pristine MWCNT containing nanocomposite resins. Therefore, charge transfer and reactive species creation lead to the enhancement of the printability of composites.

The radical formation was shown indirectly through a dye photodegradation study detailed in Example 9, where the PDA/MWCNT exhibited the highest level of dye breakdown compared to the control system of neat PDA nanoparticles (PDA NP).

### Example 8. Proposed Photosensitization Mechanism for PDA and its MWCNT Nanohybrids

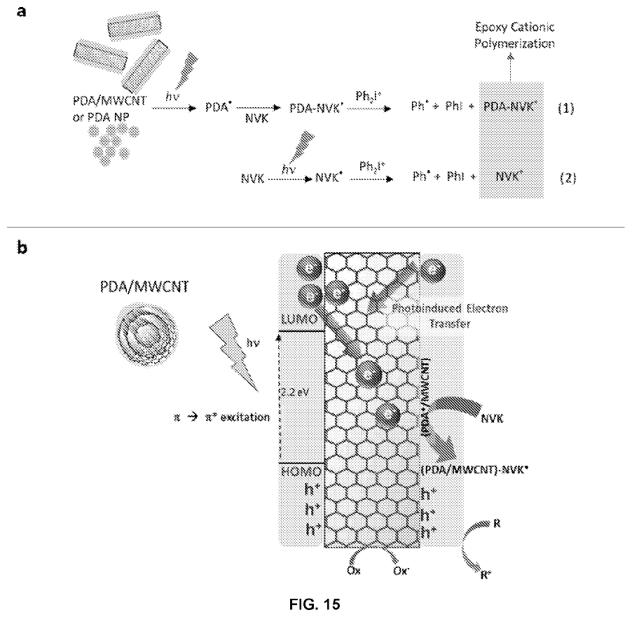

The proposed reaction route for the sensitization/co-initiation of the FRPCP process by PDA and its nanohybrids is shown in FIG. 15a. Upon irradiation, the PDA component absorbs the photon energy and is elevated to excited state and forms free radicals (free radical promoted part of FRPCP). Subsequently, it adds to the NVK C═C double bond to form a steady carbon centered radical that is more easily oxidized by the iodonium salts to form the respective stable PDA-NVK carbocation that attacks the epoxy monomer ring and initiates the ring opening cationic polymerization part of the FRPCP, by route 1 (FIG. 15a).

NVK was reported by Hua and Crivello, to be a suitable electron transfer PS for various onium salt initiators for the cationic ring opening photopolymerization of epoxides to accelerate polymerization rates with the existence of carbazole explained through an exciplex formation route (Hua, Y. & Crivello, J. V., J. Polym. Sci. A Polym. Chem. 2000, 38, 3697-3709). In the 3-component system, primary free radicals generated were reported to add to the C═C double bond of NVK and form a R-NVK radical that is subsequently oxidized by iodonium salts to yield the dye-NVK⁺ initiating species (Lalevée, J. et al., ACS Macro Lett. 2012, 1, 802-806). The role of NVK sensitizer in this context includes: (i) rendering the radical formed from PDA more readily oxidizable when it adds on to produce a more stable carbon centered radical; and (ii) allowing the PDA molecule to be part of the carbocation and thus, the growing cationic polymer chain. This will result in the PDA component being covalently bonded to the final epoxide network (FIG. 15a). Hence, the NVK sensitizer enhances mechanical property in the polymer matrix of the resulting nanocomposite material due to the generation of radicals on the surface of PDA (Sheng, W. et al., Chem. Sci. 2015, 6, 2068-2073; and Zhou, X. et al., J. Solid State Chem. 2017, 254, 55-61). Additionally, for the study carried out here, the illumination wavelengths used overlap with the absorption spectra of NVK and thus, route 2 (FIG. 15a) would be in place for the 2-component neat PIS system with Iod/NVK in the ECC resin. For the other 3-component PIS containing the PDA based sensitizer/co-initiator, the mechanism is proposed to follow route 1 (FIG. 15a) due to the reactivity enhancement (increased polymerization rate and reduced time to peak exotherm) observed, and lowering of reactivity with small amount of PDA, such as in the system with 0.125 wt % PDA NP, which suggest an interference of the PDA with original NVK sensitizing mechanism.

Synergy was observed in systems with MWCNT in proximity with the PDA layer (i.e. covalently bonded PDA/MWCNT). As charge mobility increases, the chances of recombination is reduced and thus, the efficiency of the PS/co-PI increases. Being a conjugated semiconducting molecule, PDA undergoes π-π excitation upon irradiation with suitable wavelength of light, including UV and visible light region, leading to electron hole pairs evolution as the excited electrons jump from the HOMO level to LUMO level of PDA, causing charge separation (FIG. 15b). The MWCNT acts as an electron sink for the electron hole pair generated upon photo-incidence on the PDA, while the holes have mobility in the adjacent semiconductor (PDA layer), thereby reducing charge recombination. It was reported that radicals form on the surface of the PDA layer by single electron transfer (SET, Sheng, W. et al., Chem. Sci. 2015, 6, 2068-2073) or PET. Free radicals contain at least one unpaired electron in their outer orbit band and are formed by accepting or losing an electron and could be positive/negatively charged or neutral (Gupta, P. K. in Fundamentals of Toxicology (ed P. K. Gupta) 73-85 (Academic Press, 2016)). R⁺ and Ox⁻ surface oxidative radical species are possible, though Ox⁻ less likely to happen given aspect ratio of MWCNTs.

Following the generation of PDA surface bound radicals, NVK adds on to the positively charged PDA radical (direct addition) to form a more oxidizable radical (indicated by the arrow next to NVK in FIG. 15b). Then, it is oxidized by the cationic initiator, Ph₂I⁺ (FIG. 15a). The resulting stable carbon centered PDA-NVK carbocation initiates the cationic polymerization of ECC monomers.

For PDA and its nanohybrids, active radical generation is unlikely to be through surface redox reactions (the arrow next to Ox for reduction and arrow next to R for oxidation, FIG. 15b), that generate superoxide/hydroxyl/etc. free radicals as typically in semiconductor photocatalysts. Two reasons for this inference could be given: (i) the rapid injection of electrons into the MWCNT layer leaves generated holes behind in the PDA layer. Hence, reductive reaction might not be possible as there is hardly any MWCNT surface exposed to the resin media that contains oxygen or trace moisture, and only the oxidative step would be possible; and (ii) if such free radicals were indeed generated that went on to the next steps in the polymerization, surface-initiated polymerization (SIP) would not have been possible in the case of Sheng et al.'s report in which it was due to the PDA surface bound radicals that they have achieved SIP (and FRP) of styrenic/acrylic monomers (Sheng, W. et al., Chem. Sci. 2015, 6, 2068-2073).

In the PDA/MWCNT system, the contact between the bioconjugated semiconducting PDA and conductor MWCNT creates a heterojunction and PET that gives its synergistic advantage in driving the FRPCP of the epoxy monomers. This is analogous to the study which reported on perovskite stabilized single walled CNTs forming type II heterojunction (characterized by photoemission spectroscopy) leading to excited state charge transfer upon illumination with enhanced transport of photoexcited holes and electrons by reduction of charge recombination (Li, F. et al., Adv. Mater. 2017, 29, 1602432) and also analogous to PDA-TiO₂ binding that creates a charge transfer band where the catechol served as type II PSs forming charge transfer complexes that allow injection of electrons into the TiO₂ akin to p-n junction semiconductor solar cells (Son, E. J. et al., J. Mater. Chem. A 2016, 4, 11179-11202).

The enhancement effect of PDA NP is only minimal as it potentially acts as a single semiconducting particle experiencing photoexcitation, with no adjacent channel for charge transport, giving rise to the chances of recombination and back-electron transfer. Similarly, in the discrete PDA NP and pristine MWCNT system, charge recombination and light blocking due to bare MWCNTs resulted in reduced polymerization reactivity.

The major difference between FRPCP and FRP is that the activation of the PI (photolysis of the cationic initiator) is the only light-reliant stage in FRPCP. The creation of active free radicals results in the decay of the Iod initiator. The rest of the events is via the usual cationic process (Schroeder, W. F. et al., Polym. Int. 2013, 62, 1368-1376). This light independent progression is well known as dark cure.

### Example 9. Radical Formation Evaluation Via Dye Photodegradation Study to Support Proposed Mechanism

### Dye Photodegradation Study

Dye: MB (peak absorption 665 nm)
Photocatalytic agents: PDA NP (0.1 g/L, prepared in Example 1) and 20PDA/80MWCNT hybrid nanostructures (0.1 g/L, prepared in Example 1)
Wavelength: Solar spectrum using solar simulator, unfiltered
Intensity: 1 sun intensity (approximately 100 mW/cm²)

Curing under simulated sunlight was carried out using a solar simulator equipped with Hg-Xenon lamp operated with exposure intensity of 0.9 sun irradiance i.e. 90 mW/cm² (at AM 1.5 G).

### Results and Discussion

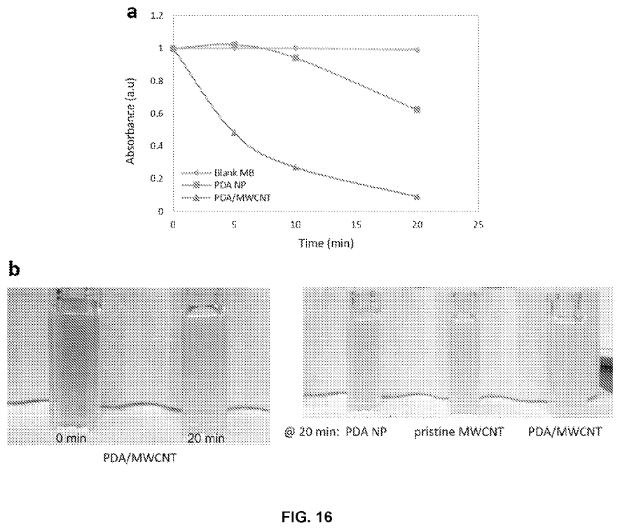

To support the proposed mechanism in Example 8, the generation of radicals from the composite hybrid particles was shown through the photodegradation of MB dye. Upon irradiation with the solar spectrum using a solar simulator, giving 5 min adsorption time prior, the samples containing the MB dye solution with PDA NP or PDA/MWCNT started to decolorize with exposure time, indicating formation of reactive species such as radicals which react with and degrade the MB molecule. This is further supported by the lowered absorbance intensity at 665 nm (FIG. 16a) and loss of color by visual appearance as shown (FIG. 16b). Blank test data showing that the MB dye (Blank MB) was not photodegraded by itself upon UV and visible light exposure was obtained from literature (Wei, F. et al., RSC Adv. 2019, 9, 6152-6162).

### Example 10. Mechanical Properties of the PDA/MWCNT Acrylate Nanocomposite System

### Compression Tests

Compression tests were carried out using an Instron Universal Tester 5566 equipped with a 50 KN loadcell. The rate of the compression plate movement was set at 5 mm/min. The honeycomb-structured samples were prepared from acrylate resin Formulation 2 by DLP printing, as described in Example 7. Honeycomb structures were printed for the compression test due to the size limitation of the printing platform of the DLP microprinter (10×10×10 mm). The PDA/MWCNT acrylate nanocomposite systems and pristine MWCNT acrylate nanocomposite systems were evaluated.

### Results and Discussion

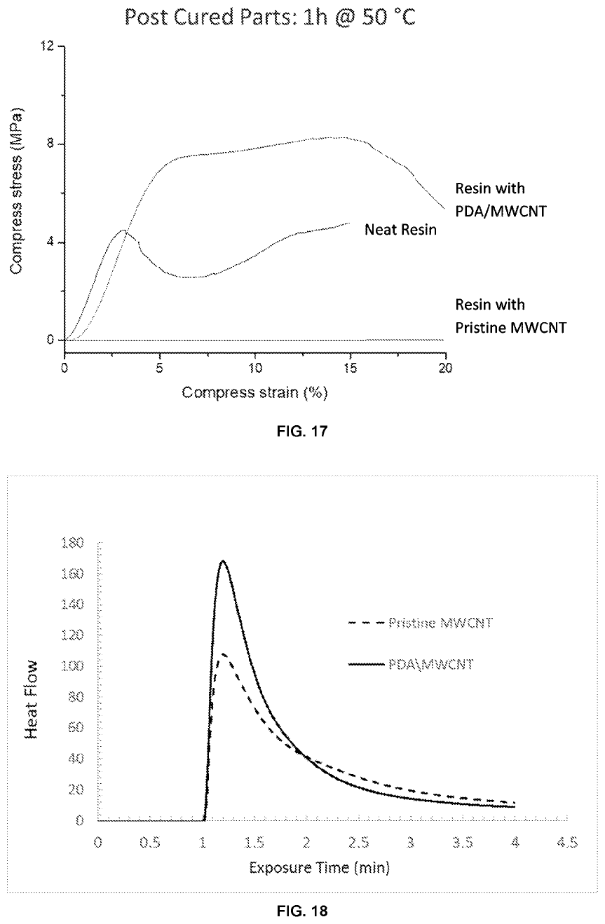

For the as-printed green parts, the neat acrylate resin was found to be much stronger than the other filled systems due to higher DOC (this is different from cure depth buildup) of the monomers as curing took place through unhindered path of light. In the case of the MWCNT filled system, the light blocking/absorbing effect is strong due to the nature of the MWCNT nanofillers. The green parts of the PDA/MWCNT acrylate nanocomposite system maintained structural integrity to enable complete printing and after the post-cure step, the mechanical properties were evaluated and the modified MWCNT system showed 90% improvement in compressive stress (FIG. 17). For acrylate systems, post-cure is generally recommended by resin manufacturers to ensure complete curing and to ensure maximum mechanical strength and maintenance of strength during the service life of the materials.

### Example 11. Photocuring Trace Through Photocolorimetry

DPC and photocalorimetry studies were carried out on the acrylate resin (Formulation 2) prepared in Example 7, by following the protocols in analytical techniques and Example 3, respectively.

### Results and Discussion

The polymerization rate (proportional to heat flow) was enhanced with PDA/MWCNT, with higher maximum rate of conversion (peak max) and conversion (FIG. 18).

### Example 12. Nanofiller Stability in PDA/MWCNT Acrylate Resin

The PDA/MWCNT dispersed acrylate resin (Formulation 2) prepared in Example 7 was taken for colloidal stability studies by following the protocol in Comparative Example 1 except the reaction mixture was left to stand in the rack for 2 days. Three samples were prepared: neat acrylate resin, 0.5 wt % pristine MWCNT in acrylate resin, and 0.5 wt % PDA/MWCNT in acrylate resin.

### Results and Discussion

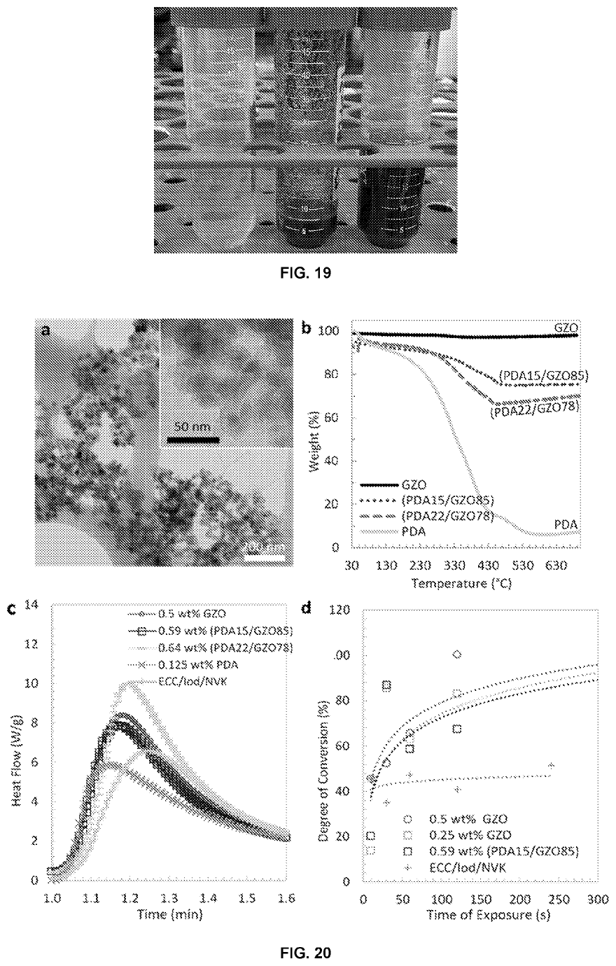

The PDA/MWCNT dispersed acrylate resin showed better visible colloidal stability over a 2-day period as opposed to separation in the pristine MWCNT system (FIG. 19).

### Example 13. PDA Surface Modification on GZO

GZO nanoparticles were modified by PDA coating via surface oxidative polymerization of DA monomers in an alkaline aqueous medium. The nanoparticles were dispersed in 0.01 M Tris HCl buffer solution (pH=8.5, 0.5 mg/mL) and subjected to horn type sonication for 5 min, followed by the addition of DA HCl at 0.25 mg/mL. The GZO:DA monomer ratio was 1:0.5. The mixture was stirred at RT for either 4 h or 24 h. The modified nanoparticles were centrifuged at 12000 rpm and washed thrice. The agglomerated particles were removed by centrifugation at 3000 rpm and the nanoparticles in the supernatant were harvested and freeze dried prior to use.

### Characterization

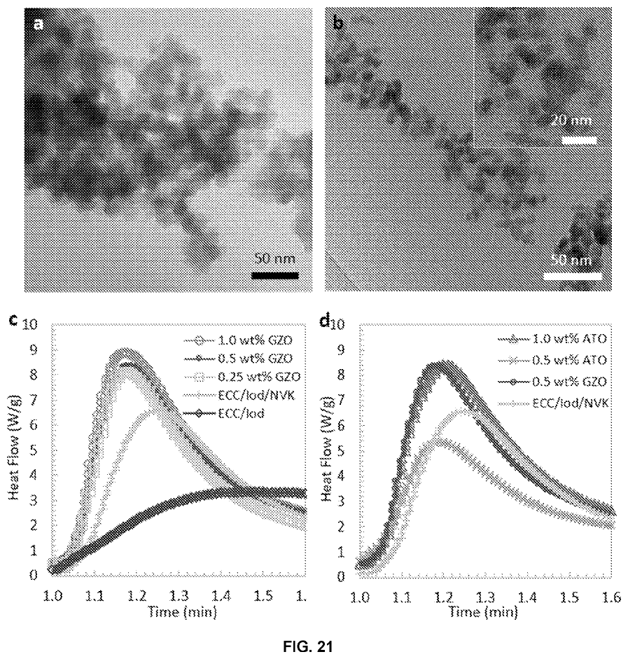

The TEM images of PDA modified GZO nanoparticles is given in FIG. 20. PDA formed a shell layer on the surface of the GZO nanoparticles. The extent of PDA grafting on GZO could be controlled by the DA monomer reactant ratio or through reaction time. Here, the time was varied to attain 2 different amounts of grafting on the GZO and was evaluated by TGA.

The wt % of the PDA component coated on the GZO nanoparticles was analyzed by TGA (FIG. 20b). The decomposition of the PDA component in the PDA modified GZO occurred in the range between 200 to 500° C. The neat GZO nanoparticles were found to be very stable in air up to 700° C. (with 1% weight loss between 250-450° C.). The GZO nanoparticles reacted with DA for 4 h, showed 16% weight loss while for 24 h reaction time, the weight loss was 23% in the given temperature range due to the decomposition of the PDA layer. Based on this, the PDA components were calculated to be 15 wt % and 22 wt % for 4 h and 24 h, respectively. The PDA/GZO samples were thus denoted as PDA15/GZO85 and PDA22/GZO78.

### Example 14. Preparation and Photocuring of Transparent Conductive Oxides (TCO) and its PDA Hybrid Nanocomposite Resins

GZO and ATO are plasmonic band-gapped TCOs. The ECC epoxy monomers were mixed with GZO, ATO or PDA NP or PDA/GZO nanoparticles prepared in Example 13 in appropriate amounts and subjected to ultrasonication (10 min) and balanced with NVK/Iod at (3 wt %/2 wt %) followed by further sonication (10 min). The resin was then mixed in a planetary centrifugal mixer at 2000 rpm for 5 min.

TABLE 3
Labels and their respective system.

| Label | System comprising |
|---|---|
| 0.25 wt % or 0.5 wt % or | NVK/lod (3 wt %/2 wt %) |
| 1.0 wt % GZO or ATO | GZO or ATO (0.25 wt % or 0.5 wt % |
| | or 1.0 wt %) |
| | ECC monomer |
| 0.59 wt % | NVK/lod (3 wt %/2 wt %) |
| (PDA15/GZO85) | Coated nanohybrids comprising 15 wt % |
| | PDA and 85 wt % GZO (0.59 wt %) |
| | ECC monomer |
| 0.64 wt % | NVK/lod (3 wt %/2 wt %) |
| (PDA22/GZO78) | Coated nanohybrids comprising 22 wt % |
| | PDA and 78 wt % GZO (0.64 wt %) |
| | ECC monomer |

The wt % indicated above is based on the total weight of each system.

The photocuring of the resins was carried out by following the protocol in Example 2.

### Example 15. Epoxy Polymerization of Photoactive TCO Nanocomposite Resins Trace by DPC

The epoxy polymerization of the photoactive TCO nanocomposite resins prepared in Example 14 was evaluated by photocalorimetry by following the protocol in Example 3.

### Results and Discussion

The heat flow curves for the various PIS with ECC monomer is given in FIG. 21c-d. The peak time to maximum reaction rate was reduced with increased GZO content from 18 s for the neat ECC/Iod/NVK system (i.e. no GZO) to 10.5-11 s with GZO (0.25 wt % to 1 wt %). Therefore, the rate of polymerization increases with GZO content. The enthalpy of polymerization and thus the DOC was found to increase by 11% with the addition of 0.5 wt % GZO, with respect to the ECC/Iod/NVK system. Another type of TCO evaluated with epoxy resin system is ATO, which was found to be less effective in this given set of constraints in terms of doping percentage, particle size and morphology. The reduction in heat enthalpy rate with a low percentage of the ATO and even PDA, compared to the ECC/Iod/NVK system, suggests that the role of the semiconducting/LSPR particles could be more than just sensitization, i.e. they are potentially co-initiators together with the third component NVK in the PIS. This will be discussed in detail in Example 18.

The DPC heat flow curves for the PIS with different PDA/GZO nanohybrids and neat GZO and PDA NP is given in FIG. 20c. All the samples with GZO contain the same amount at 0.5 wt %. PDA grafted GZO showed changes in peak maximum time from 9 s to 9.6 s and 18 s to 12 s, for 0.125 wt % PDA and ECC/Iod/NVK, respectively. There was also an increase in the overall heat of reaction and conversions compared to neat resin system and that containing 0.125 wt % PDA NP. The heat of polymerization and thus DOC was found to increase by 24% with the addition of 0.64 wt % PDA22/GZO78 with respect to the neat ECC/Iod/NVK system, and 30% with respect to the 0.125 wt % PDA NP PIS system. The PDA/GZO sensitized/co-initiated the polymerization process and there was an improvement over the 0.125 wt % PDA NP containing PIS. Nevertheless, the improvement is not as significant as observed for the bioconjugated semiconductor-conductor, PDA/MWCNT based PIS, for the FRPCP of ECC monomers.

### Example 16. DOC of GZO Epoxy Resin Systems from FTIR Analysis

The GZO epoxy resin systems prepared in Example 14 were taken for UV-vis spectroscopy, and FTIR analysis to determine DOC by following the protocol in Example 4.

### Results and Discussion

For curing in the UVA region between 315-400 nm, where the PDA/GZO nanohybrids and GZO nanoparticles absorb strongly, the trend of the effect of the various PS/co-PI is in agreement with that of the DPC analysis (wavelength: 290-660 nm, FIG. 20c) as analyzed by FTIR (FIG. 20d). There is no significant difference in the ECC polymerization reactivity between the 0.5 wt % GZO and the PDA/GZO nanohybrids though all 3 materials showed enhancement in the DOC (based on overall enthalpy) when compared to ECC/Iod/NVK or 0.125 wt % PDA PIS. At 60 s irradiation time, the DOC increased by approximately 15% (from 45% to ˜60%) for GZO and PDA/GZO compared to ECC/Iod/NVK system. For the PDA/GZO PIS, the improvement was the same as analyzed by DPC. For pure GZO nanoparticles at 0.5 wt %, the enhancement with the irradiation concentrated in the UVA (315-400 nm; 18 mW/cm²) region was also approximately 25%, whereas with 18 mW/cm² illumination in the broader spectrum (DPC source lamp), it was found to be only 11%.

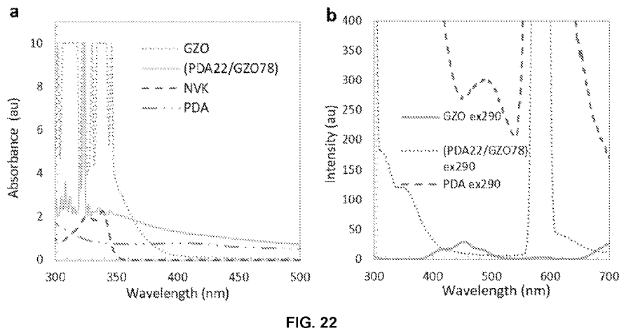

This was attributed to the strong absorption of GZO below 400 nm, beyond which it tapers off to zero (FIG. 22a) with reference to the UV-Vis absorbance spectra. It was also found that the PDA NP exhibited strong absorption below the mid UV region (<320 nm) and with a slight hump between 390-440 nm. The PDA modified GZO exhibited the characteristics of both the components it was made up of. It showed absorption below 400 nm (peak at 320 nm), and gently sloped down to a broad band in the 400 to 600 nm range. NVK, the third component sensitizer/co-initiator in the 3 component PIS for FRPCP, showed strong absorption between 310 and 350 nm.

### Example 17. PL Spectroscopy of GZO Nanoparticles and Nanohybrids

The GZO nanoparticles and nanohybrids prepared in Examples 13-14 were taken for PL spectroscopy.

### Results and Discussion

The emission spectra resulting from the recombination of charge carriers in semiconductors (Guan, S. et al., Top. Catal. 2018, 61, 1585-1590) give information on the electron hole movement of the particles upon excitation at a given wavelength, suitably in the absorption range of the particles. GZO exhibited a broad fluorescence (defect level emission peak: 400-520 nm, FIG. 22b) upon excitation with UV-Vis light (290 nm) which is attributed to charge recombination of free electrons due to the intrinsic shallow traps and deep level vacancy defect sites (Babar, A. R. et al., J. Phys. D: Appl. Phys. 2008, 41, 135404) arising from Ga doping. On the other hand, PDA emitted between 440 and 550 nm (concentrations were kept constant at 1 wt % solution, FIG. 22b). At the excitation wavelength given, the fluorescence peak was found to be quenched in the PDA/GZO nanohybrids (FIG. 22b), indicating a charge transfer effect reducing recombination frequency.

### Example 18. Proposed Reaction Mechanism for PDA/GZO Nanohybrids

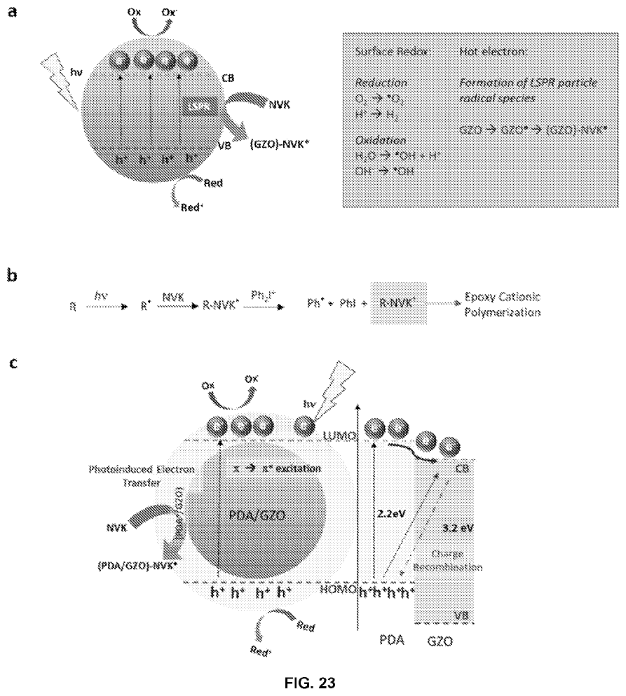

Plasmonic nanoparticles could also be utilized to initiate polymerization by Localized Surface Plasmon Resonance (LSPR)-induced electron transfer leading to radical formation. With the GZO and ATO TCO nanoparticles, the electrons from the valence band (VB) are excited upon irradiation with UV-Vis light and with the photon energy gained, the electrons jump to the conduction band (CB), which are known as surface plasmon induced hot carriers electrons (FIG. 23a). The free radical part of the FRPCP is possible through the surface redox species generated, such as superoxide radical anions and hydroxyl radicals known as the reactive oxidative species (ROS). The presence of suitable PI and PS in the resin system leads to photoinduced polymerization. Another hot electron mediated route for Au plasmonic nanoparticles triggered photopolymerization was proposed (non-surface redox route) where the formation of Au· adds to the active C═C bond of the acrylic monomers and form the initiating radical Au·—C—C species which propagate FRP (Ding, T. et al., ACS Photonics 2017, 4, 1453-1458). Similarly, the polymerization sequence could also proceed with the TCO nanoparticle bound radical (GZO·) adding on to NVK as shown in FIG. 23a.

With the generation of free radicals, the reaction proceeds by the addition at the C═C bond of NVK to form a stable carbon centred radical that is more easily oxidized by the iodonium salts to form the respective stable R-NVK carbocation that attacks the epoxy monomer ring and initiates the ring opening cationic polymerization part of the FRPCP via the route given in FIG. 23b. The details of this process had been explained in Example 8.

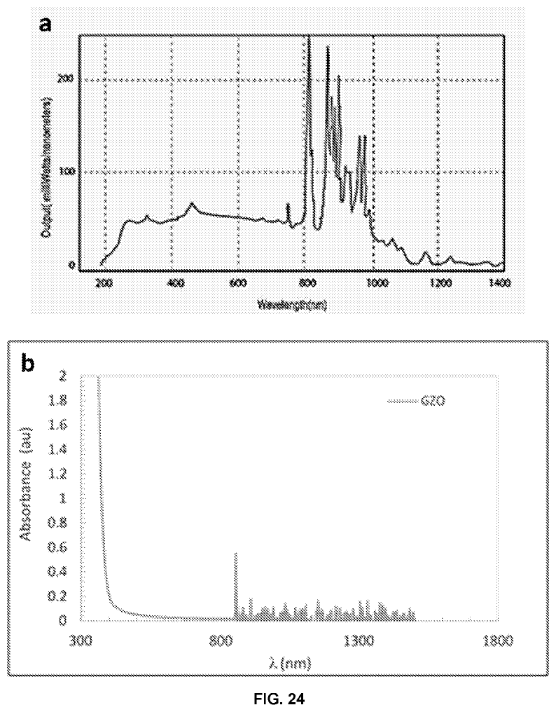

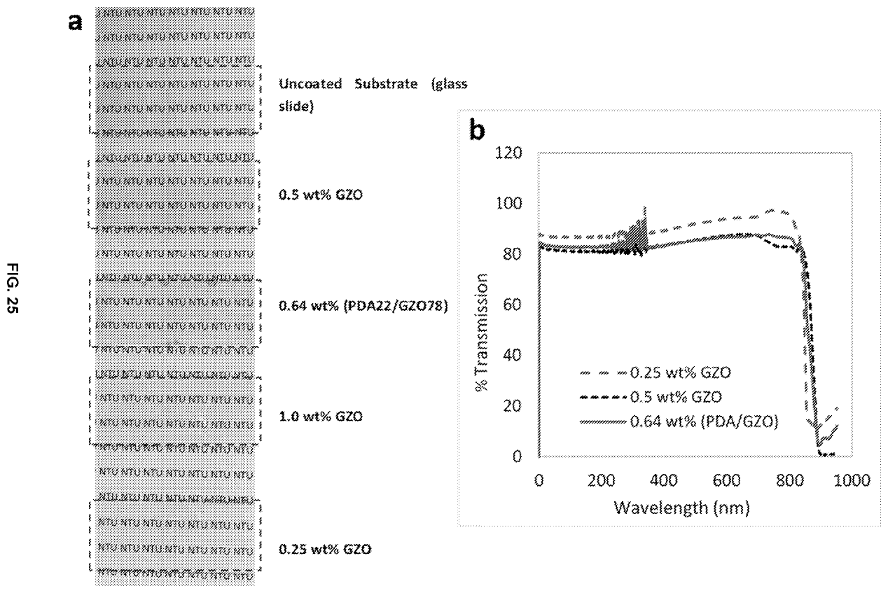

Upon the excitation of the electrons due to surface plasmon, the electron transfer could lead to photoinitiation from hot electron effect or the energy could decay and get emitted as heat leading to nanoheating effect to trigger polymerization. In this instance, no nanoheating effect was postulated to be in place as upon solar simulator illumination at 0.9 sun intensity, the samples containing the various GZO and its nanohybrids cured to tack free conditions within s and there was no rise in temperature recorded in all the films. The upper limit emission wavelength of the Hg—Xe lamp also did not coincide with the near IR absorption of GZO which does not occur till 1400 nm (FIG. 24).

### Example 19. PDA/GZO Nanohybrids

Metals or any plasmonic/band gapped conductor/conductor materials form heterojunction with a semiconductor material, which upon illumination under suitable conditions and subsequent electron-hole pair generation, trigger efficient charge transfer (electron injection) and to prevent recombination though the ‘hot electron mechanism’ which is akin to dye sensitization in solar cells (when conductor-semiconductor are in direct contact). ‘Near field enhancement’ effect is also possible when metal-semiconductor are not in direct contact (Fan, W. & Leung, M. K., Molecules 2016, 21, 180; Gelle, A. & Moores, A., Curr. Opin. Green Sustain. Chem. 2019, 15, 60-66; and Christopher, P. & Moskovits, M., Annu. Rev. Phys. Chem. 2017, 68, 379-398).

The PDA region is directly in line with the light rays. Hence, upon light incidence, the semiconductor domain is activated rather than the LSPR effect of GZO as GZO is not in the direct line of the light rays (FIG. 23b). The mechanism could be explained in a similar manner to that discussed for PDA/MWCNT. The electrons are excited from the HOMO level of PDA to LUMO level and they are injected into the conduction band of GZO nanoparticle. Direct injection (Fan, W. & Leung, M. K., Molecules 2016, 21, 180; and Nam, H. J. et al., Chem. Eur. J. 2012, 18, 14000-14007) has also been proposed with the electrons being injected from the HOMO level of PDA into the bottom of the CB of GZO. However, hot electron cooling effect could cause the electron to undergo recombination and reduce the efficiency of the PS/co-PI. Previously in the PDA/MWCNT system, the MWCNT is a conductor with high affinity for electrons and charge carrier mobility, which then transports them away from the heterojunction to prevent recombination, leading to the synergy observed. However, for the PDA/GZO system where the GZO is a bandgapped conductor, the electron recombination due to hot electron cooling or back electron transfer effect appeared to be potential causes for the limited increase in efficiency.

PDA/GZO was found to show limited advantage in terms of polymerization speed and conversion. However, the films formed were highly transparent (83% visible light transmission, FIG. 25) due to transmittance of the plasmonic nanoparticles in the UV-Vis region, which could be advantageous in applications that require transparency/translucency or needs to be light colored such as thermal insulation coatings for windows for building climate control. Other advantages of plasmonic nanoparticles include the local heating effect when irradiated in the NIR-IR region for polymer cure rate enhancement on top of the photo processes, and to trigger actuation in 3D printed parts or the nanocomposite materials, due to the strong absorption in the near IR and IR region.

PDA based nanohybrids have never been reported in PIS for polymerization of any sort of polymers. PDA based nanohybrid photosensitive materials, hot electron injection type plasmonic hybrid (semiconducting-conducting) materials and TCOs have been explored in the photovoltaic and photocatalysis arena. Notably, this is the first time they are applied in photopolymerization. PDA biomolecule-based semiconductor-conductor type hybrid nanomaterials as heterogenous PSs/co-initiators for photopolymerization opens vast possibilities in designing suitable PSs/initiators for light curing of many compounds in the bio/medical/polymer arena due to biocompatibility of PDA as the conjugated semiconductor.

1. A formulation comprising:
a hybrid composite material;
at least one photopolymerizable monomer;
one or both of a free radical photoinitiator and an oxidizable radical co-producer, wherein
the hybrid composite material comprises:
an organic semiconducting material; and
a conductive material, wherein
the organic semiconducting material is bonded to the conductive material.

2. The formulation according to claim 1, wherein the organic semiconducting material is selected from one or more of the group consisting of a bioconjugated biomolecule semiconductor and a conjugated organic material with semiconducting properties.

3. The formulation according to claim 2, wherein:
(Ai) the bioconjugated biomolecule semiconductor is selected from one or more of the group consisting of a polydopamine, a polyepinephrine, a polymelanine, a polyeumelanin; and
(Bi) the conjugated organic material with semiconducting properties is a monomer or an oligomer or a polymer formed from monomers with extended π-conjugated systems.

4. The formulation according to claim 1, wherein the conductive material is selected from one or more of the group consisting of a conductive carbon material and a plasmonic, transparent conductive metal oxide, and metal particles.

5. (canceled)

6. The formulation according to claim 1, wherein the ratio of the organic semiconducting material to conductive material is from 0.1:99.9 to 25:75 by weight, such as from 5:95 to 25:75 by weight, such as from 15:95 to 25:75 by weight, such as 20:80 by weight.

7. The formulation according to claim 1, wherein the formulation further comprises at least one cationic photoinitiator.

8. The formulation according to claim 1, wherein the hybrid composite material has at least one dimension that is less than 500 nm.

9. The formulation according to claim 1, wherein the conductive material comprises a first conductive material and a second conductive material, and wherein the organic semiconducting material is bonded to the first conductive material and the second conductive material or vice versa.

10. The formulation according to claim 9, wherein the first and second conductive materials are selected from a conductive material as described in claim 4 or claim 5, provided that the first and second conductive materials are not the same.

11. The formulation according to claim 1, wherein the organic semiconducting material comprises a first organic semiconducting material and a second organic semiconducting material, and wherein the conductive material is bonded to the first organic semiconducting material and the second organic semiconducting material or vice versa.

12. The formulation according to claim 1, wherein the hybrid composite material is selected from the list:
(i) polydopamine bonded to multiwalled carbon nanotubes; and
(ii) polydopamine bonded to GZO.

13. A kit of parts comprising:
(A) a first formulation comprising a hybrid composite material as described in claim 1 and a first portion of at least one photopolymerizable monomer; and
(B) a second formulation comprising a second portion of the at least one photopolymerizable monomer and one or both of a free radical photoinitiator and an oxidizable radical co-producer.

14. The formulation according to claim 1, wherein the formulation further comprises one or more of the following components:
(ai) a co-initiator;
(aii) a co-sensitizer;
(aiii) a photostabilizer;
(aiv) an inhibitor
(av) a rheology modifier; and
(avi) a tackifier.

15. The formulation according to claim 1, wherein the at least one photopolymerizable monomer is a monomer having a functional group selected from one or more of the group consisting of thiolene, epoxide, acrylate, and cyclic oxide ring.

16. (canceled)

17. The formulation according to claim 1, wherein the at least one photopolymerizable monomer is a monomer selected from one or more of the following list:
(bi) epoxycyclohexylmethyl-3′,4′-epoxycyclohexane carboxylate;
(bii) bis(oxiran-2-ylmethyl) cyclohexane-1,2-dicarboxylate;
(biii) 2-[[4-[1-methyl-1-[4-(oxiran-2-ylmethoxy)phenyl]ethyl]phenoxy]methyl]oxirane;
(biv) 2-[2,2-bis(oxiran-2-ylmethoxymethyl)butoxymethyl]oxirane;
(bv) methyl methacrylate;
(bvi) 4-prop-2-enoyloxybutyl prop-2-enoate;
(bvii) 2,2-bis(prop-2-enoyloxymethyl)butyl prop-2-enoate;
(bix) 6-[4-[1-methyl-1-[4-(4-oxohex-5-enoxy)phenyl]ethyl]phenoxy]hex-1-en-3-one;
(bx) hexane-1,6-dithiol;
(bxi) [4-(sulfanylmethyl)phenyl]methanethiol; and
(bxii) 6,6-bis(3-oxo-5-sulfanyl-pentyl)-1,11-bis(sulfanyl)undecane-3,9-dione.

18. (canceled)

19. The formulation according to claim 1, wherein one or more of the following apply:
(di) the oxidizable radical co-producer, when present, is selected from one or more of the group consisting of a carbazole, an amine, and a silane;
(dii) the free radical photoinitiator, when present, is selected from one or more of the group consisting of a Type I and a Type II free radical photoinitiator; and
(diii) when the formulation or the kit of parts comprises a cationic photoinitiator, the cationic photoinitiator is an iodonium salt and/or a sulfonium salt.

20. The formulation according to claim 1,
wherein one or both of the following apply:
(ei) the amount of the free radical photoinitiator is from 0.1 to 5 wt % of the total weight of the formulation; and
(eii) the amount of the oxidizable radical co-producer is from 0.1 to 5 wt % of the total weight of the formulation.

21. The formulation according to claim 7, wherein the amount of the cationic photoinitiator is from 0.1 to 5 wt % of the total weight of the formulation.

22. A method of initiating and/or sensitizing photopolymerisation, comprising:
(gi) mixing a hybrid composite material as described in claim 1 with a composition comprising:
at least one photopolymerizable monomer; and
one or both of a free radical photoinitiator and an oxidizable radical co-producer
to form a mixture; and
(gii) exposing the mixture to a light in order to provide a polymer product.

23. (canceled)

24. (canceled)

25. (canceled)

26. A method of additive manufacture, the method comprising the steps of:
(hi) providing a mixture comprising:
a hybrid composite material as described in claim 1;
at least one photopolymerizable monomer; and
one or both of a free radical photoinitiator and an oxidizable radical co-producer;
(hii) forming a layer using the mixture according to a design;
(hiii) subjecting the layer to light to provide a polymer; and
(hiv) repeating steps (hii) and (hiii) until the desired design is complete.

27. (canceled)

28. (canceled)

29. (canceled)
